(19) United States
(12) Patent Application Publication
(10) Pub. No.: US 2026/0100064 A1
(43) Pub. Date: Apr. 9, 2026

(54) METHOD FOR MACHINE ANALYSIS OF FLOOR PLAN IMAGES

(71) Applicant: 2717981 Alberta Inc., Edmonton (CA)

(72) Inventors: Mrinal MANDAL, Edmonton (CA); Naresh JHA, Edmonton (CA); Zhongguo XU, Edmonton (CA); Mehadi SAYED, Edmonton (CA)

(21) Appl. No.: 19/228,092

(22) Filed: Jun. 4, 2025

Related U.S. Application Data
(60) Provisional application No. 63/704,233, filed on Oct. 7, 2024.

(51) Int. Cl. G06V 20/70; G06F 30/13; G06Q 30/0283; G06Q 50/08; G06T 7/11; G06V 10/764; G06V 10/82; G06V 30/10

(52) U.S. Cl. CPC G06V 20/70; G06F 30/13; G06Q 30/0283; G06Q 50/08; G06T 7/11; G06V 10/764; G06V 10/82; G06V 30/10

(57) ABSTRACT

A system for processing an input architectural floor plan image is provided herein. The system includes a processor and a computer-readable medium with sequences of instructions that include an object detector to detect and classify a plurality of objects in an architectural floor plan image to output object data, a text analyzer to identify and extract text from the architectural floor plan image to output machine-readable text data, a segmentation module comprising a third set of sequences executed by the computer processor to divide the architectural floor plan image into at least one region, and a semantic labeler to determine a semantic label for each region of the at least one region based, at least in part, on the object data and the text data from the architectural floor plan image.

### FIELD OF THE DISCLOSURE

The present disclosure relates generally to information systems. In particular, the disclosure relates to a method for machine analysis of floor plan images.

### BACKGROUND OF THE DISCLOSURE

Architectural floor plans are documents for conveying building information among designers, engineers, and clients. Architectural floor plans play a significant role in designing, modeling, and understanding indoor spaces. Various annotations are generally used to illustrate the layout, style, scale based on the experience and knowledge of designers and engineers. Floor plans are generally stored as raster images (e.g., in “png” format) in the application process, though they are typically designed and built by use of advanced vector software (e.g., PlanSwift, AutoCAD).

Floor plans can be broadly divided into two categories: simple brochure type (SBT) and complex architectural type (CAT). FIG. 1A show two prior art SBT examples: one in rectangular shape and another in round shape. The SBT floor plans allow non-experts and clients (e.g., home buyers and renters) to easily understand and obtain information. FIG. 1B shows one CAT example that contains more detailed information compared to the SBT, which is useful for building specialists. As shown in FIGS. 1A and 1B, the SBT and CAT floor plans consist of lines, curves, symbols, and textual data, presenting the contextual relationships among these elements.

Automated analysis of floor plans enhances user productivity and accuracy, though research on automatic object detection within architectural floor plans has been limited. For example, the wall and symbols detection in a floor plan are required for the generation of three-dimensional (3D) building information models (BIM). Floor plan analysis is also widely used in other industries, such as virtual reality (VR) exploration of buildings, indoor navigation and modeling, and apartment price estimation.

As the floor plan contains a large quantity of heterogeneous information, it is laborious and time consuming for humans to manually extract the diverse information, such as the size and location of an element (e.g., doors). Automatic floor plan analysis has been a long-standing problem within industries. Automatic floor plan analysis typically involves different tasks, such as wall detection, object (e.g., windows, doors) detection, and room (e.g., bedroom, bathroom) detection and labeling. When using automated processing for detecting and identifying objects within floor plan images, detection results from the processes can be used in the generation of three-dimensional (3D) models, and in the cost estimation of a building. The incorrect object detection can result in information missing in the BIM and add extra post-processing works for the cost estimators. Therefore, an efficient and robust object detection method improves the efficiency of the floor plan analysis processes.

The state-of-the-art object detection methods for floor plans are mainly based on deep learning models, which have shown to be promising candidates. However, the direct use of a deep learning network on a floor plan in these methods is inefficient, since the deep learning networks were developed originally for addressing general object detection problems.

The techniques for floorplan object detection can be broadly categorized into rule-based methods and learning-based methods. It is known to detect objects such as doors by first finding the openings between the wall segments. The doors were identified using the SURF technique. It is also known to assume that the openings between the wall segments were either doors or windows. The line arc in the openings was used to distinguish the doors and windows. Morphological erosion and dilation are often used to remove the noisy lines in a floor plan. The text information was then detected by conducting a statistical analysis. The rule-based methods typically have limited generalizability as some pre-defined hyper-parameters need to be tuned by the specialists. In addition, the rule-based methods in the literature were constructed based on the SBT floor plans (e.g., FIG. 1A). These methods would not perform well for the CAT floor plans (e.g., FIG. 1C) that include more complex information.

Previous techniques have proposed the YOLO (You Only Look Once) architecture for object detection in 2015. Subsequently, multiple versions of YOLO algorithms have been proposed by different researchers. The YOLO architecture is an end-to-end neural network that predicts the bounding boxes and class probabilities simultaneously. Previous techniques have also used YOLOv2 to detect 12 object classes in the floor plans. In this method, a tiling strategy was used to improve the detection performance on small-size objects in large floor plan images (e.g., 5400×3600 pixels). The large floor plan image was first split into various tiles with certain size (e.g., 224×224 pixels) and then fed into the deep learning network.

As shown in FIG. 1B, the CAT floor plans contain more detailed information than the SBT floor plans. However, the existing research is mostly focused on the SBT floor plans. In addition, these works detect the objects in the floor plans by directly using the object detectors that were developed for general object detection.

There is a need for an efficient and accurate method for automatically extracting building parameters from architectural floor plan images by combining object detection, text analysis, and image segmentation techniques. There is also a need for a deep learning network that is tailored to efficiently detect diverse objects in a CAT floor plan, and for a deep learning network that can semantically segment an architectural floorplan image that contains a large quantity of heterogeneous information.

### SUMMARY OF THE DISCLOSURE

According to an aspect, there is provided a system for processing an input architectural floor plan image, the system comprising a computer processor and a non-transitory computer-readable medium comprising one or more sequences of instructions for detecting objects in a floor plan using a neural network, the system comprising: an object detector comprising a first set of sequences executed by the computer processor to at least detect and classify a plurality of objects in an architectural floor plan image to output object data, a text analyzer comprising a second set of sequences executed by the computer processor to at least identify and extract text from the architectural floor plan image to output machine-readable text data, a segmentation module comprising a third set of sequences executed by the computer processor to at least divide the architectural floor plan image into at least one region, and a semantic labeler comprising a fourth set of sequences executed by the computer processor to at least determine a semantic label for each region of the at least one region based, at least in part, on the object data and the text data from the architectural floor plan image, wherein the system quantifies building parameters of the at least one region based on the semantic label of the at least one region for generating a structured, machine-interpretable representation of the architectural floorplan.

According to an aspect, there is provided a computer-implemented method for processing an input architectural floor plan image to determine building parameters for the architectural floor plan, the method comprising: performing at least one object detection step on the architectural floor plan image for detecting and classifying a plurality of objects in the architectural floor plan image to output object data, the object data including object classes and object locations for the plurality of objects within the architectural floor plan image, performing at least one text analysis step for identifying and extracting text from the architectural floor plan image to output text data, the text data including textual content and textual content locations within the architectural floor plan image, performing at least one segmentation step for dividing the architectural floor plan image into at least one region, determining a semantic label for each region of the at least one region based, at least in part, on the object data and the text data, and quantifying the building parameters of the at least one region based on the semantic label of the at least one region.

According to another aspect, there is provided a computer-implemented, deep-learning method for processing an input architectural floor plan image, the method comprising: executing a trained deep learning model to process the architectural floor plan image, performing, via the deep learning model, at least one object detection step on the architectural floor plan image for detecting and classifying a plurality of objects in the architectural floor plan image to output object data, the object data including object classes and object locations for the plurality of objects within the architectural floor plan image, performing, via the deep learning model, at least one text analysis step for identifying and extracting text from the architectural floor plan image to output text data, the text data including textual content and textual content locations within the architectural floor plan image, performing, via the deep learning model, at least one segmentation step for dividing the architectural floor plan image into at least one region, determining, via the deep learning model, a semantic label for each region of the at least one region based, at least in part, on the object data and the text data, and quantifying, via the deep learning model, the building parameters of the at least one region based on the semantic label of the at least one region.

### BRIEF DESCRIPTION OF THE DRAWINGS

Embodiments will now be described, by way of example only, with reference to the attached Figures, wherein:

FIG. 1A shows a prior art schematic of two SBT examples, one with a rectangular shape and another with a round shape;

FIG. 1B shows a prior art schematic of one CAT example that contains more detailed information compared to the SBT examples in FIG. 1A;

FIG. 1C shows a prior art schematic of another CAT example;

FIG. 2 shows a block diagram of an embodiment of a machine analysis of a floor plan framework (MAFP) that may be included as part of the system of the present disclosure;

FIG. 3 shows a block diagram of an exemplary embodiment of the data preprocessing module for use within the system of FIG. 2;

FIG. 4 shows an exemplary block diagram of an embodiment of the object detector that may be provided within the framework shown in FIG. 2;

FIG. 5A shows a flowchart diagram of an embodiment of the Conv module with kernel size and the stride values both equal to one;

FIG. 5B shows a flowchart diagram of an embodiment of the bottleneck module which includes two Conv modules;

FIG. 5C shows a flowchart diagram of an exemplary SPFF module that includes sequential MaxPool2D operations;

FIG. 5D shows a flowchart diagram of an exemplary backbone module that includes a Conv module that has at least a regular 2D convolution, a batch normalization, and a Sigmoid Linear Unit (SiLU) activation function;

FIG. 6 shows a block diagram of an exemplary embodiment of the AC-CBAM module;

FIG. 7A shows a block diagram of the internal processing paths of an embodiment of the detection convolution block within the detection module;

FIG. 7B shows a block diagram of the of the internal processing paths of an embodiment of the bounding box postprocessing block within the detection module;

FIG. 7C shows a block diagram of the of the internal processing paths of an embodiment of the classification postprocessing block within the detection module;

FIG. 8 shows an exemplary block diagram of an embodiment of the segmentation module for semantic segmentation of the architectural floorplan image;

FIG. 9A shows a schematic diagram of an embodiment of the room boundary decoder module;

FIG. 9B shows a schematic diagram of an embodiment of the MRBAM sub-module;

FIG. 9C shows a schematic diagram of an embodiment of the Conv Unit within the MRBAM sub-module of FIG. 9B;

FIG. 10 shows a diagram of an image from an example R3D dataset that is provided in the examples of the present disclosure;

FIG. 11 shows a set of four feature maps that are output from an embodiment of the backbone module within the object detector;

FIG. 12 shows a feature map that is output by the D1-b output of the detection convolution block along Path1 in FIG. 4;

FIG. 13 shows the same feature maps from FIG. 13, except the color values are obtained by selecting the index of the maximum across all channels of the feature map;

FIG. 14 shows a graphical representation of a PR curve of performance for an example embodiment of the system of the present disclosure;

FIG. 15 shows a comparison of a shallow feature map outputted from the MLP between the YOLOv8 and the ArchNetv2-a;

FIG. 16 shows another floor plan detection example on the comparison of the shallow feature map outputted from the MLP between the YOLOv8 and the proposed ArchNetv2-b;

FIG. 17 shows an example of the visualization of object detection results predicted by the proposed ArchNetv2;

FIG. 18 shows exemplary visualization of the T_{b2} calculation within an example embodiment of the Concat module;

FIG. 19 shows an example of a kernel within the boundary-refinement-block convolutional layer of the Concat module;

FIG. 20 shows floor plan segmentation results produced by the proposed method for a first image from the R3D dataset;

FIG. 21 shows floor plan segmentation results produced by the proposed method for a second image from the R3D dataset;

FIG. 22A shows a first graphical representation of the training loss for the prior art RBGA-CNN, and the FloorNet model of the present disclosure;

FIG. 22B shows a second graphical representation of the training loss for the prior art RBGA-CNN, and the FloorNet model of the present disclosure;

FIG. 23A shows an example of a well-learned room boundary (RB) feature map that is an input for this MRBAM unit;

FIG. 23B shows an example of a room type (RT) feature map that is another input for this MRBAM unit;

FIG. 23C shows an example of a fused features produced within the MRBAM unit; and

FIG. 23D shows an example of a well-predicted room boundary that is generated from the MRBAM unit.

### DESCRIPTION OF THE EMBODIMENTS

It will be understood by those of ordinary skill in the art that the embodiments described herein may be practiced without these specific details. In other instances, well-known methods, procedures and components have not been described in detail so as not to obscure the embodiments described herein. It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description. It will also be noted that the use of the term “a” or “an” will be understood to denote “at least one” in all instances unless explicitly stated otherwise or unless it would be understood to be obvious that it must mean “one”.

As used herein, the terms “comprises” and “comprising” are to be construed as being inclusive and open ended, and not exclusive. Specifically, when used in the specification and claims, the terms “comprises” and “comprising”, and variations thereof mean the specified features, steps or components are included. These terms are not to be interpreted to exclude the presence of other features, steps or components.

As used herein, the terms “about” and “approximately” are meant to cover variations that may exist in the upper and lower limits of the ranges of values, such as variations in properties, parameters, and dimensions.

Throughout this disclosure, the term “architectural floorplan image” is used to refer to the visual input processed by the described systems and methods. It should be understood that this term encompasses both a single, unified floor plan image and multiple, separate images contained within a floorplan document. The system and method of the present disclosure are capable of processing each of these images individually to determine building parameters, regardless of whether the input is a single composite image or a collection of distinct images within a document.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

The embodiments described herein are exemplary (e.g., in terms of materials, shapes, dimensions, and constructional details) and do not limit by the claims appended hereto and any amendments made thereto. Persons skilled in the art will appreciate that there are yet more alternative implementations and modifications possible, and that the following examples are only illustrations of one or more implementations. The scope of the disclosure, therefore, is only to be limited by the claims appended hereto and any amendments made thereto.

### System Architecture

In an embodiment of the present disclosure, there is provided a system for processing an input architectural floor plan image. The system comprising and a non-transitory computer-readable medium comprising one or more sequences of instructions for detecting objects in a floor plan using a neural network. The system generally comprises an object detector, a text analyzer, a segmentation module, and a semantic labeling module. The object detector comprises a first set of sequences executed by the computer processor to at least detect and classify a plurality of objects in the architectural floor plan image in order to output object data. The text analyzer comprises a second set of sequences executed by the computer processor to at least to identify and extract text from the architectural floor plan image to output the machine-readable text data. The segmentation module comprises a third set of sequences executed by the computer processor to at least divide the architectural floor plan image into at least one region, and the semantic labeling module comprises a fourth set of sequences executed by the computer processor to at least to determine a semantic label for each region of the at least one region (by applying rules-based logic) based, at least in part, on the object data and the text data for the architectural floor plan image. The system also quantifies building parameters of the at least one region based on the semantic label of the at least one region for generating a structured, machine-interpretable representation of the architectural floorplan.

In an additional embodiment, the object data includes object classes and object locations for the plurality of objects within the architectural floor plan image, and the machine-readable text data includes textual content and textual content locations within the architectural floor plan image

In at least some embodiments, the building parameters of the at least one region form a structured, machine-interpretable digital model of the architectural floorplan; and wherein the model is structured to enhance the computer processor functional capabilities for automated architectural analysis by transforming unstructured data in the architectural floorplan image into structured machine-interpretable design data for downstream processes.

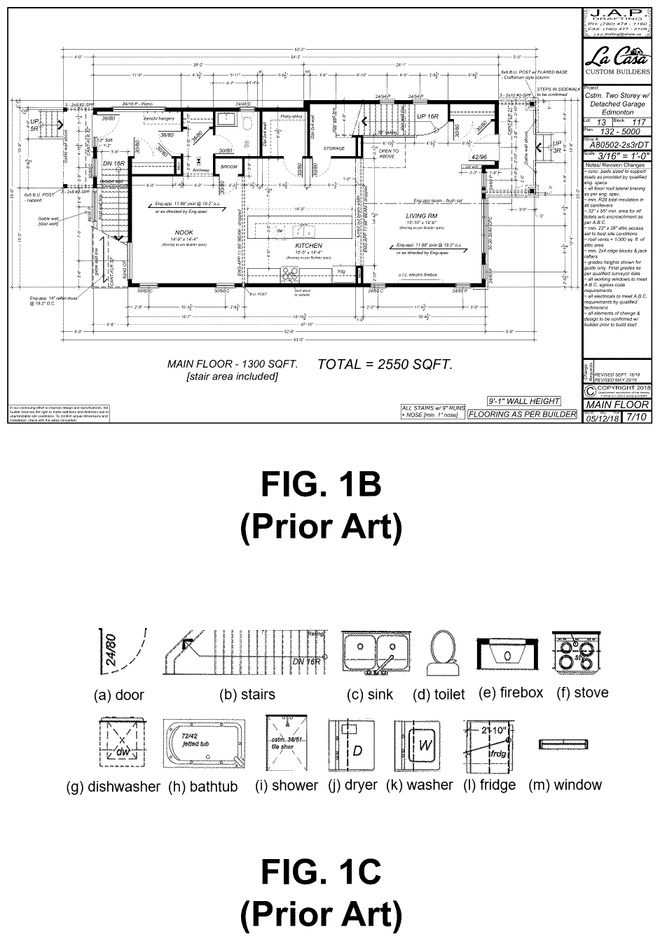

Referring to FIG. 2, there is provided a block diagram of an embodiment of a machine analysis of a floor plan framework (MAFP) that may be included as part of the system. As shown in FIG. 2, the system (including the MAFP) includes the object detector (OBJDET), the text analyzer (TXTANL), and the segmentation module (SEGMT). In at least some embodiments (such as shown in FIG. 2), the sematic labelling module (LBLDET) is included as part of the segmentation module (SEGMT), while in at least some other embodiments the semantic labeler can be included as a separate, standalone module that communicates with the object detector (OBJDET), text analyzer (TXTANL), and segmentation module (SEGMT).

In certain embodiments, the object detector (OBJDET), text analyzer (TXTANL), and segmentation module (SEGMT) operate in parallel. This parallel processing may reduce the overall processing time compared to a sequential approach where each module would be executed one after the other. By performing these tasks concurrently, the system can efficiently leverage computational resources and provide faster analysis of the input architectural floor plan image.

In at least some embodiments, the the building parameters determined by the system may comprise at least one of: room dimensions, room areas, object counts, object types, and spatial relationships between objects.

In additional embodiments, the system may be additionally configurable for outputting the determined building parameters to a user interface, and/or utilizing the determined building parameters for at least one of: generating a building information model (BIM), estimating construction costs, and verifying building code compliance.

In additional embodiments, the system may also be configurable for generating a Bill of Materials report based at least on the determined building parameters for each semantically labelled region, the report being formatted for automated input into an architectural design or construction management software system.

In at least some embodiments, the system may include a data preprocessing module that performs data preprocessing on the input architectural floorplan images to improve the performance and robustness of subsequent processing steps. The data preprocessing by the data preprocessing module may include, for example, resizing the images to a standard size, normalizing pixel values, removing noise, and correcting for distortions.

In an embodiment, the object detector is configurable to perform pre-processing on the architectural floor plan images, the pre-processing comprising: dividing the plurality of architectural floor plan images into at least a training dataset, a validation dataset, and a testing dataset, annotating each image within at least the training dataset and the validation dataset to generate corresponding ground-truth annotation data, applying at least one data augmentation technique to images in at least the training dataset and the validation dataset, resizing the augmented images to a predetermined input dimension suitable for processing by a deep learning model, and resizing detection results obtained from the deep learning model back to an original dimension of the architectural floor plan images for visualization.

In an additional embodiment, the data preprocessing module is provided as part of the object detector, and the object detector also comprises a training and testing module that operates together with the data preprocessing module and the main modules of the object detector. An example training process for use within the training and testing module is provided in Example 8 of the present disclosure.

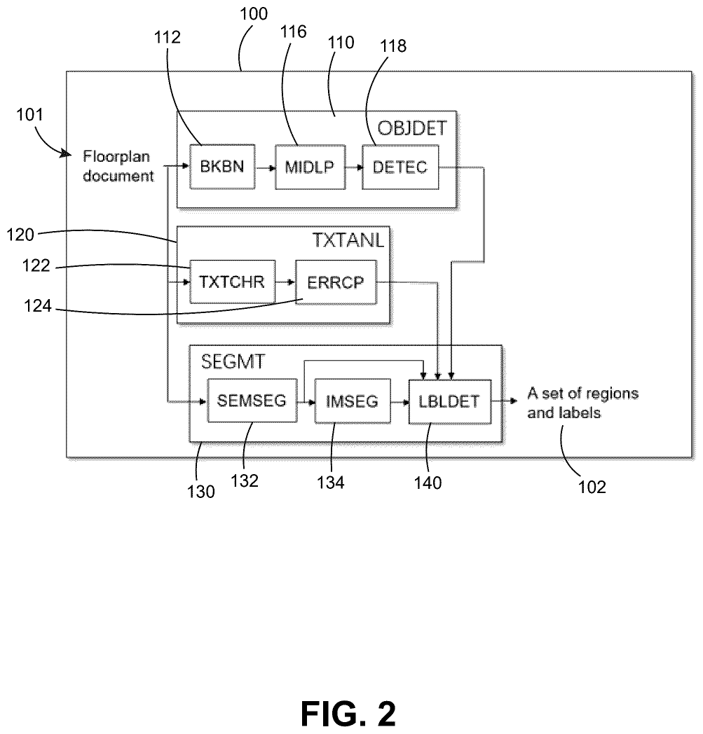

Referring to FIG. 3, there is provided a block diagram of an exemplary embodiment of the data preprocessing module 200 for use within the system of the present disclosure. In the specific embodiment provided in FIG. 3, a set of dataset preprocessing steps that can be executed by the data preprocessing module 200 for processing the architectural floorplan image is illustrated, where these steps may include initial data acquisition, dataset splitting, groundtruth generation, and data augmentation, to thereby generate at least an augmented training set, an augmented validation set and an augmented testing set. In this embodiment, example datasets (which are provided in Example 1 of the present disclosure) are used to demonstrate the effect of the data preprocessing module 200. As described in Example 1, the example datasets include a complex architectural floor plan (CAFP) dataset that consists of 54 floorplan images collected from the professional house builders. Each image has a constant size of 2200×3400. The initial data acquisition starts with the CAFP dataset. The CAFP dataset then undergoes dataset splitting into a training set, a validation set, and a testing set. In parallel, the CAFP dataset undergoes groundtruth generation, which includes object class annotation and bounding box annotation. The dataset also undergoes data augmentation that includes floorplan image augmentation and bounding box location adjustment. The outputs of the preprocessing steps are an augmented training set, an augmented validation set, and an augmented testing set. Additional details on the example dataset and the details of the preprocessing of this example dataset are provided below in Example 1.

For optimal performance, the size of the input floor plan image may be varied. Different input sizes may affect both the accuracy and processing speed of the system architecture.

### Object Detector

In an embodiment, the object detector includes a neural network (such as a convolutional neural network (CNN)) that is applied to the data from the architectural floorplan image for outputting the object data of the plurality of objects.

In at least some embodiments, the neural network of the object detector (OBJDET) includes at least one of a backbone module (BKBN), a mid-level processing module (MIDLP), and a detection module (DETEC). Generally, the floorplan image or floorplan document is input into the backbone module (BKBN) of the object detector (OBJDET). The backbone module (BKBN) extracts features from the floorplan image or floorplan document. These features are then processed by the mid-level processing module (MIDLP) to enhance the features. The detection module (DETEC) then uses the enhanced features to detect and classify objects within the floorplan document. The output of the object detector (OBJDET) is object data, including object classes and object locations within the architectural floorplan image.

In an additional embodiment, the backbone module specifically generates a set of floorplan features maps from the floorplan image, and the mid-level processing module learns from and tunes this initial set of floorplan features maps to generate the enhanced set of floorplan feature maps. The detection module classifies the plurality of objects based on the enhanced set of floorplan feature maps from the mid-level processing module, effectively producing model predictions (i.e., object bounding box size/locations and object classifications).

Various suitable techniques can be applied to enhance the classification performance of the object detector. For example, the backbone module may utilize an architecture with a feature pyramid network to extract multi-scale features, and the mid-level processing module may employ an attention mechanism (such as a spatial attention mechanism) to focus on relevant spatial locations within the feature maps, improving object localization. Furthermore, the detection module may utilize an architecture with suitable modifications (e.g., modifications to the loss function) to optimize for the specific characteristics of the plurality of objects in the architectural floor plan image. These combined enhancements may provide more efficient and accurate neural network-based processing for detecting diverse visual objects within the architectural floorplan image, potentially offering superior performance compared to state-of-the-art methods. The proposed features of the object detector may provide improvements to the module for enhancing object detection performance, particularly for complex architectural floorplan images.

In at least some embodiments, the object detector is configurable with multiple heads, where each head operates independently to localize and classify objects, enabling efficient detection across different scales. This multi-head design may include additional heads beyond what is used in existing object detection systems to provide for more robust detection of smaller objects in the architectural floorplan image (e.g., windows).

In at least some embodiments, the processing within the object detector occurs at least partially sequentially, with the processing in the backbone module initiating before the processing in the mid-level processing module, and the processing in the mid-level processing module initiating before the processing in the detection module.

In an embodiment, the backbone module comprises a series of convolution layers and pooling layers that generate feature maps.

In an embodiment, the backbone module is configurable such that it includes a plurality of layers, where earlier layers extract the basic features, such as the edges, while the later layers capture the object-level features that are beneficial for object detection. To prevent loss of localization information within the later layers due to down sampling, the backbone module may additionally be configurable to include at least four outputs for use by the mid-level processing module. An example of the outputted features maps from the backbone module is described in more detail below in Example 3.

In an additional embodiment, the backbone module comprises a CNN selected from the group comprising VGG16, ResNet, and DenseNet.

In an embodiment, the mid-level processing module includes at least one attention mechanism for tuning the floorplan feature maps to generate the enhanced set of floorplan feature maps.

In an additional embodiment, the at least one attention mechanism of the mid-level processing module includes an AC-CBAM, where the AC-CBAM is configurable as a CBAM attention mechanism that is integrated with at least one C2f module to suppress invalid features and emphasize advantageous features. The AC-CBAM can help the ArchNetv2 learn the shape feature and textual feature of the objects. The AC-CBAM can also help improve the performance of the ArchNetv2 by assigning higher weights for the shape and textual features and lower weights for the irrelative features.

In an exemplary embodiment, the AC-CBAM comprises the CBAM attention mechanism, and first and second C2f modules that are integrated with the CBAM attention mechanism. The CBAM attention mechanism suppress invalid features learned from the first C2 module, and the second C2f module retunes the advantageous features. Said another way, the MLP module comprises: a first path having a C2f module in an upstream position, and a second path having the AC-CBAM in a downstream position, the AC-CBAM configurable by aggregating the C2f module with the CBAM, and further configurable to suppress invalid features and enhance advantageous features for object detection tasks to thereby preventing loss of shallow and deep information during an upsampling process and adaptively tuning features used for the subsequent detection module.

In at least some embodiments, the AC-CBAM module is positioned in a downstream path of the mid-level processing module (while retaining a C2f module in the upstream path) to tune the features used by the detection module, thereby facilitating the preservation of both shallow and deep information during the upsampling process and the generation of the enhanced floorplan features (e.g., enhanced floorplan feature maps) from the mid-level processing module. Various other arrangements of the AC-CBAM and C2f modules may also be in the mid-level processing module, such as using AC-CBAM on both the upstream and downstream paths and using AC-CBAM in the upstream path and retaining C2f in the downstream path. However, these other arrangements may be less effective at preserving shallow and deep information within the enhanced floorplan features.

In an embodiment, the detection module the detection module comprises a plurality of detection heads that are configurable to operate independently for localizing and classifying the plurality of objects, where at least one of the plurality of detection heads is specifically adapted to detect small-sized objects, thereby expanding inputs of contextual information, increasing a number of candidate proposals, and improving detection performance on small-size objects within the architectural floor plan image.

In an embodiment, the detection module is configurable for executing an objection detection process that includes receiving the enhanced set of floorplan features (e.g., enhanced floorplan feature maps) from the mid-level processing module, and processing the enhanced set of floorplan features through a plurality of detection convolution blocks for determining the bounding boxes and classifications for the plurality of objects within the architectural floor plan image.

In an additional embodiment, the plurality of detection convolution blocks include at least a bounding box postprocessing (BBP) block and a classification postprocessing (CP) block.

In another additional embodiment, the detection module is configurable to use rectangular bounding boxes for identifying and classifying the object data for the plurality of objects in the architectural floorplan image by predicting a location and size of the rectangular bounding boxes during classification of the plurality of objects.

In yet another additional embodiment, the detection module further includes a Non-Maximum Suppression (NMS) that is applied to an output of the plurality of detection convolution blocks.

Object Detector with YOLOv8 Architecture

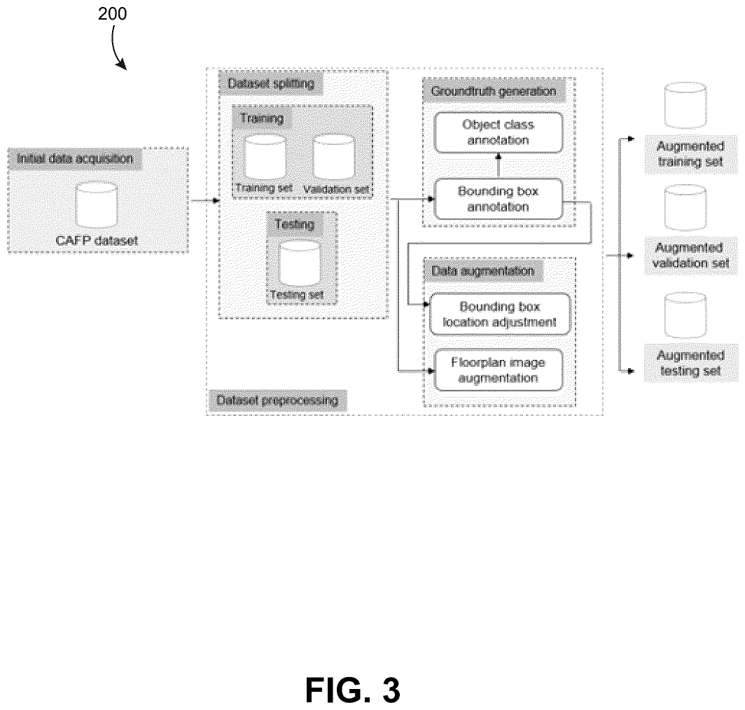

Referring to FIG. 4, there is provided an exemplary block diagram of an embodiment of the object detector 110 (which may also be referred to as the ArchNetv2 architecture). As illustrated in this block diagram and described above, the object detector 110 comprises the backbone, mid-level processing (MLP), and detection modules 112, 116, 118. In this exemplary embodiment, the object detector 110 is configurable as a modified version of the YOLOv8 architecture. YOLOv8 is a state-of-the-art, single-stage object detector known for its speed and accuracy.

In the embodiments of the object detector that are configurable as a modified version of the YOLOv8 architecture, the backbone module may reuses at least some elements of the backbone of YOLOv8 to extract the features of the architectural floorplan image, and the set of feature maps generated by the backbone module includes at least four feature maps with multi-scale information for the floorplan features. (e.g., at least one more output than is typically generated by the backbone of YOLOv8).

In the specific embodiment provided in FIG. 4, the backbone module 112 of the object detector 110 receives the input floorplan image 101 and extracts the specific features B1, B2, B3, B4, B5, B6, B7, B8, B9, and B10 using a series of Conv modules 112b and C2f modules 112a, culminating in a spatial pyramid pooling fast (SPPF) module 112c.

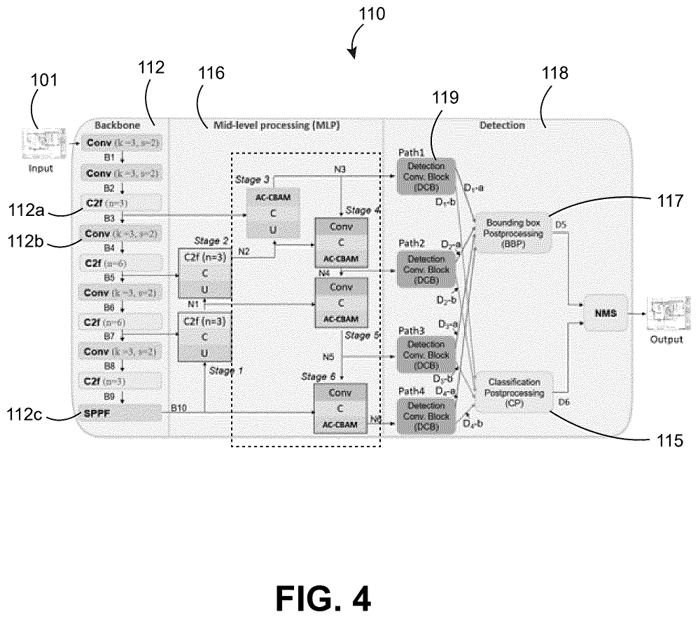

Additional details of the architecture for the backbone module 112 will now be described with reference to FIG. 5A to 5D, where FIGS. 5A to 5D provide a set of block diagrams that illustrate exemplary logic of modules that can be used in the backbone module 112 for the object detector shown 110 in FIG. 4. FIGS. 5A, 5B, 5C, and 5D specifically depict embodiments of the Conv module, Split module, ‘n’ Bottleneck module, and Concatenation module, respectively. In the embodiment shown in FIG. 5A, the Conv module is structured with k=1, s=1, where “k” and “s” refer to the size of kernel and the stride value in the convolutions, respectively. In the logic of the Conv module, an initial feature map CF1 is processed via a first Conv module before being split in a split module, with one branch having ‘n’ sequential bottleneck modules for feature refinement.

In the embodiment shown in FIG. 5B, the bottleneck module includes two Conv modules, with k=3 and s=1, while also including a skip connection for additive feature fusion. The Conv modules may have a stride value of 2 which can reduce the size of the output features maps). In the embodiment shown in FIG. 5C, an exemplary SPFF module is provided, where this SPPF module includes sequential MaxPool2D operations (with a kernel size of 5×5), followed by a concatenation and a Conv module. In the SPPF, three 2D MaxPool operations (with size 5×5) are applied sequentially after 1×1 convolution, and each layer is then concatenated followed by another 1×1 convolution.

Lastly, in the embodiment provided in FIG. 5D, the backbone module includes a Conv module that has at least a regular 2D convolution, a batch normalization, and a Sigmoid Linear Unit (SiLU) activation function. Additional details on the backbone module and the performance of the various embodiments of the backbone module (as shown in FIGS. 5A to 5D) are provided in Examples 2 and 3 of the present disclosure.

In the embodiments of the object detector that are configurable as a modified version of the YOLOv8 architecture (e.g., the object detector shown in FIG. 4), the mid-level processing module may take in the at least four inputs from the backbone module, and the mid-level processing module itself may use at least six sub-modules (referred to hereinafter as stages), which is at least two additional stages beyond the stages that would be present within the original YOLOv8 architecture. The mid-level processing module may also include a convolution block attention module (e.g., a module with the Conv and AC-CBAM blocks described below) which may improve the performance of the object detector compared to the original YOLOv8 architecture.

With these modifications to the YOLOv8 architecture, a finer detection head is provided. Detection heads are effectively a feature map with a resolution of M*M. Each cell in the feature map is used to propose an object. If two objects fall into the same cell, only the larger one will be detected.

The typical YOLOv8 architecture has three detection heads (e.g., M=20,40,80). The modifications to the YOLOv8 provided for in the objection detection module of the present disclosure include at least additional, finer detection head (e.g., M=160) to improve the detection performance. This finer detection head enables each cell of the corresponding feature map to better distinguish and detect individual objects, even when they are small or close together in the architectural floorplan image. This finer detection head can help detect the smaller neighboring objects that might otherwise share a cell in other coarser detection heads (e.g., N6). These modifications also provide a feature map that is a semantic response in the CNN training. The use of AC-CBAM may help the object detector pay attention to more relevant features that are beneficial for object detection.

In the specific embodiment provided in FIG. 4, the mid-level processing (MLP) module 116 of the object detector 110 includes AC-CBAM modules and processes the features from the backbone module 112 through at least six stages (Stages 1 to 6). The AC-CBAM modules are integrated into Stages 3, 4, 5, and 6 of the mid-level processing module 116 such that each stage of the at least six stages includes upsampling (U), concatenation (C), Conv, and AC-CBAM blocks, and such that each stage of the at least six stages generates a unique feature maps (e.g., feature maps N1, N2, N3, N4, N5 and N6).

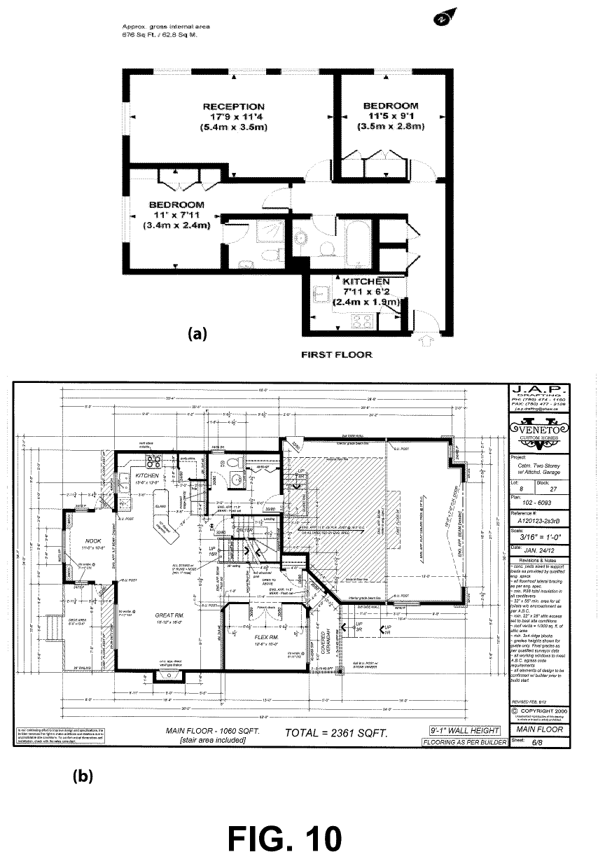

In an additional embodiment such as shown in FIG. 4, Stage 1 includes upsampling, concatenation and C2f steps that are all performed sequentially. The output feature maps of SPPF 112c (i.e., B10) in the backbone module 112 are used as the input of the upsampling unit, and the upsampled output is then concatenated with the B7 feature maps from the backbone module 112. The C2f module is then used to process the concatenated feature maps, and the output is fed as the input of Stage 2. Stage 2 has a similar or identical structure to that of Stage 1, and Stage 3 is similar to Stage 1 (or Stage 2) for the first two operations, where N2 is unsampled and concatenated with B3 (from the Backbone). However, for Stage 3, the concatenated feature maps are then fed into the AC-CBAM module instead of a C2f module. Additional details of the AC-CBAM module are described below with reference to FIG. 11. The output of the AC-CBAM in Stage 3 is used as one head for the detection module. Stage 4 in the AC-CBAM involves a Conv block, a concatenation operation and an AC-CBAM block. The Conv block uses a stride of 2 to downsample the feature maps. The output of Stage 2 is used in this concatenation. The output of Stage 4 is also used as one head for the detection module. Stages 5 and 6 have the same structure as Stage 4. However, the concatenation in Stage 5 uses the output of Stage 1 while Stage 6 uses the output of the SPPF in the backbone module. The output of Stages 5 and 6 can then be used by the detection module.

Within the object detector of the present disclosure, various structures of attention modules may be more effective on different data sets with different characteristics. Referring to FIG. 11, there is provided a block diagram that illustrates an exemplary AC-CBAM module 300 that may be provided within the mid-level processing module 116 of the object detector 110 in FIG. 4.

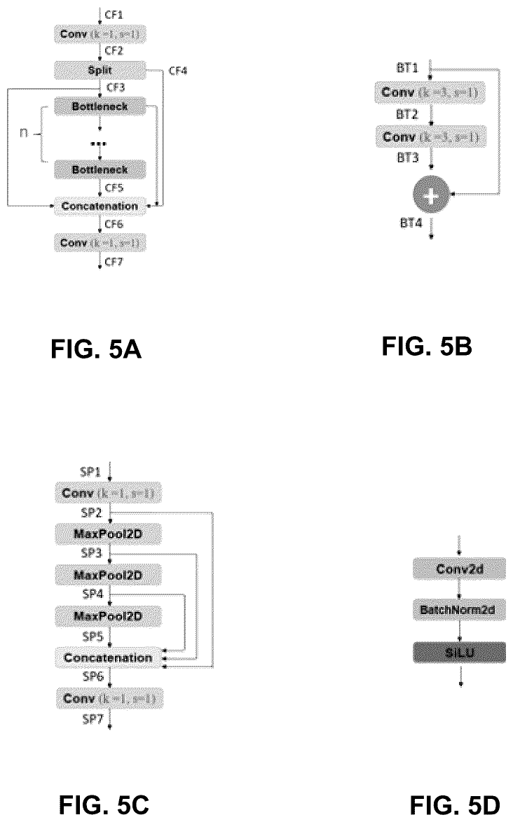

In the specific embodiment provided in FIG. 6, the AC-CBAM module 300 receives an input feature map A1, which is processed through a C2f module (n=3) 310 to generate feature map A2. The characters “U” and “C” refer to upsampling and concatenation operations, respectively. The feature map A2 is then passed through the CBAM module 320, which consists of a Channel Attention Module (CAM) and a Spatial Attention Module (SAM). Within the CBAM module 320, the CAM 320a refines the feature map A2 based on channel-wise attention, generating feature map CA1. The CA1 is multiplied with A2 to generate feature map CA2. The SAM 320b then refines CA2 based on spatial attention, generating feature map CA3. The CA3 is multiplied with CA2 to generate feature map A3. Finally, A3 is processed through another C2f module (n=1) 330 to generate the output feature map A4. An example of the output from the mid-level processing module is described in more detail in Example 4 of the present disclosure.

In at least some additional embodiments of the object detector described herein, the mid-level processing module includes CBAM to use full contextual information from the feature maps, which may allow for more robust and accurate object detection, even in challenging scenarios where objects are occluded or surrounded by clutter.

In the embodiments of the object detector that are configurable as a modified version of the YOLOv8 architecture, the detection module may process the enhanced set of floorplan feature maps on at least four parallel processing paths that correspond to the at least four feature maps from the backbone module. Effectively, the detection module may have at least four heads (instead of three as provided in the YOLOv8) to improve the detection performance.

The detection module receives at least four inputs from the mid-level processing module, and each input goes through an identical or similar detection convolution block (DCB). The detection module may also include the bounding box postprocessing (BBP) block and a classification postprocessing (CP) block.

In an example embodiment, the detection convolution block for each input is configurable as a unique detection convolution block, where the resolutions for each of the four parallel processing paths (Path 1, 2, 3, and 4) are 160×160, 80×80, 40×40, and 20×20, respectively. The lower resolutions processing paths are designed to capture bigger-size objects and the higher resolution processing paths are design to capture for smaller-size objects.

In an additional embodiment, the detection convolution block for each input to the detection module has at least two parallel branches (e.g., top and bottom branches) that individually predict localization (e.g., top branch) and classification (e.g., bottom branch) of each object of the plurality of objects in the architectural floorplan image. Each branch of the at least two parallel branches include a stack of a plurality of CNN layers. The at least two branches are used to predict the classifications and localizations of the objects, respectively.

In the specific embodiment provided in FIG. 4, an example detection module 118 is shown, which receives inputs N3, N4, N5, and N6 from the mid-level processing module 116 along the four parallel processing paths (Path 1, Path 2, Path 3, Path 4), where each path includes a detection convolution block 119 that generates outputs Dk-a and Dk-b. Each detection convolution block 119 has at least two parallel branches that predict the localization (top branch) and classification (bottom branch) of the objects, and at least three convolutions are performed in each branch of the detection convolution block 119. Within the detection module 118, the top outputs (D1-a, D2-a, D3-a, D4-a) from the four detection convolution blocks 119 are channeled into the BBP block 117, while the bottom outputs (D1-b, D2-b, D3-b, D4-b) from the four detection convolution blocks 119 are channeled into the CP block 115.

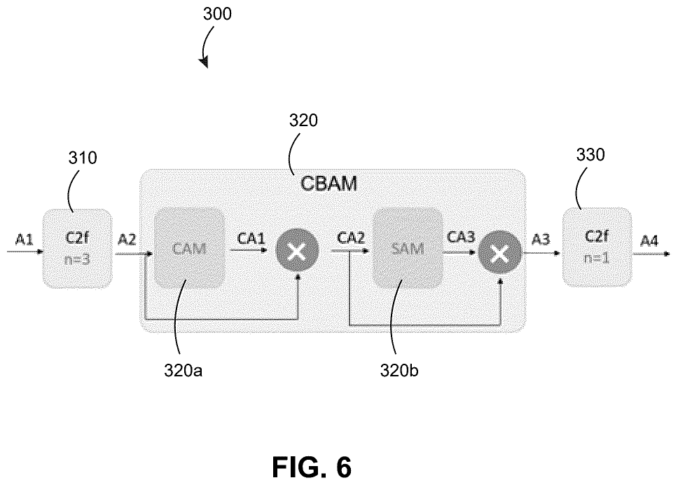

Referring to FIGS. 7A to 7C, there is provided three separate block diagrams that illustrate exemplary logic of the blocks that may be used within the detection module 118 of the object detector 110 shown in FIG. 4. FIGS. 7A to 7C illustrate the internal structure and operation of the blocks within detection module 118, which collectively may generate object detections from the enhanced features (e.g., enhanced feature maps) received from the mid-level processing module 116.

In the embodiment provided in FIG. 7A, the detection module 118 includes the detection convolution block 119, which may act as a core processing unit within the detection module 118. The detection convolution block 119 takes a feature map “D” as input and processes it along two parallel branches 119a, 119b. The top branch 119a refines bounding box predictions (Dk-a) through a series of Conv modules and a Conv2D layer, while the bottom branch 119b refines class predictions (Dk-b) using a similar structure. The internal feature maps (D1, D2, D3, D4) within each DCB 119 may generally maintain a consistent size of M×M× C.

In the embodiment provided in FIG. 7B, the detection module 118 includes the BBP block 117. The BBP block 117 receives the Dk-a outputs from the detection convolution blocks 119 and reshapes them in one or more reshape modules 117a (e.g., BBP1, BBP2, BBP3, and BBP4), and then concatenates the reshaped Dk-a output in a concatenation module 117b to generate another reshaped output BBP5. The output BBP5 is then processed through a Conv2d module 117c to generate the final bounding box prediction output BBP6.

In the embodiment provided in FIG. 7C, the detection module 118 includes the CP block 115. The CP block 115 is structured to receives the Dk-b outputs from the detection convolution blocks 119 and reshapes them in one or more reshape modules 115a (CP1, CP2, CP3, and CP4), concatenates them in the concatenation module 115b to generate CP5, representing the classification predictions.

In an additional embodiment not shown in FIGS. 7A to 7B, Non-Maximum Suppression (NMS) may be applied to the outputs of the BBP block (as shown in FIG. 7B) and the CP block (as shown in FIG. 7C), which generates the output of the object detector (OBJDET). This may aid in selecting more accurate and non-redundant detections within the detection module 118.

In at least some embodiments, the NMS algorithm produces at least two outputs as the outputs of the object detector: the location and size of the selected bounding boxes (N×4) and the corresponding object class labels (N×1), where N is the number of detected objects.

In at least some embodiments of the object detector described herein, the objection detection module employs the at least four detection heads within the detection module for generating a greater number of object proposals compared to other techniques that use only three detection heads. The object detector may thereby be configurable with a multi-scale detection module and may be particularly effective at detecting objects of varying sizes within a floor plan, such as both large staircases and smaller features like windows and dishwashers.

Examples 5 and 6 of the present disclosure provide further details on specific embodiments of the structure of the detection convolution blocks (DCBs). Example 7 of the present disclosure provides an example of the visualization of object detection results predicted by the embodiment of the object detector shown in FIG. 4, as well as an exemplary performance analysis of the object detector.

### Text Analyzer

As provided above, the system also includes the text analyzer that is configurable to identify and extract text from the architectural floor plan image to output text data, the text data including textual content and textual content locations within the architectural floor plan image. In an embodiment, the text analyzer comprises a text character recognition module (TXTCHR) for recognizing text characters within the architectural floor plan image to generate the text data, and an error correction and parsing module that is structured to perform error corrections and parsing on the text characters of the text data (i.e., modify the text data) such that the text data generated from the text analyzer includes a plurality of recognizable strings. In the context of the present disclosure, it can be said that the text analyzer performs at least one text analysis step for identifying and extracting text from the architectural floor plan image to output the text data.

In at least some embodiments, the text analyzer (TXTANL) is configurable to receive the architectural floorplan image or floorplan document. The architectural floorplan image is received by the text character recognition module (TXTCHR) of the text analyzer (TXTANL). The text character recognition module (TXTCHR) identifies text characters within the floorplan document. The error correction and parsing module (ERRCP) then performs the error corrections on the text characters to modify the text data and generate recognizable strings. The output of the text analyzer (TXTANL) is the text data, including textual content (containing the recognizable strings) and textual content locations that define the location of the textual content within the architectural floorplan image.

In an additional embodiment, the text character recognition module includes a CNN-based OCR technique, and the error correction and parsing module includes a natural language processing (NLP) technique.

In at least some embodiments, the text analyzer (TXTANL) can be implemented using a combination of machine learning techniques. For example, the text character recognition module (TXTCHR) may employ a Convolutional Recurrent Neural Network (CRNN) architecture. This architecture can be well-suited for recognizing sequences of characters in images, as it combines the feature extraction capabilities of CNNs with the sequence modeling capabilities of Recurrent Neural Networks (RNNs). The CRNN may be trained using, for example, Connectionist Temporal Classification (CTC) loss, which allows for end-to-end training without requiring precise alignment of the text characters. While the above example is specific to the use of a CRNN and a CTC loss function for the training of the text character recognition module, it will be readily understood that a variety of suitable neural network models can be used within the text character recognition model as described herein.

In the same exemplary embodiment, the error correction and parsing module (ERRCP) may utilize a beam search algorithm with a language model trained on architectural terminology to correct errors and generate meaningful strings. The error correction and parsing module may also incorporate a lexicon of common architectural terms and abbreviations to further improve accuracy.

While specific examples of the text analyzer (TXTANL) have been detailed above, it is understood that the configuration of the module is not limited to these particular implementations. Other techniques for text character recognition and error correction may be employed. For instance, the text character recognition module (TXTCHR) could utilize a transformer-based OCR model, which leverages self-attention mechanisms to capture long-range dependencies in the text. Similarly, the error correction and parsing module (ERRCP) could employ a rule-based system that applies predefined rules to correct common errors and parse the text data. The specific choice of techniques may depend on the characteristics of the floor plan images and the desired level of accuracy and performance.

In an embodiment, the error correction and parsing module utilizes a technique selected from the group consisting of a beam search algorithm and a language model.

### Segmentation Module

As provided above, the system includes the segmentation module (SEGMT) that is configurable to divide the architectural floor plan image into at least one region. The segmentation module may be configurable to deal with architecture floorplan images (and objects within the floorplan images) which have complex geometries. The segmentation module of the present disclosure may generally utilize semantic segmentation techniques, where these semantic segmentation techniques can classify each pixel as a certain type of pixel (i.e., wall or non-wall pixel).

In an embodiment, the segmentation module comprises a semantic segmentation module (SEMSEG) that is configurable to classify each pixel of the plurality of pixel of the architectural floorplan image into a class of a plurality of classes of region boundaries or a class of a plurality of classes of region areas. The segmentation module also includes an image segmentation module (IMSEG) that is configurable to divide the architectural floorplan image into at least one region based on the class of each pixel plurality of pixels in the architectural floorplan image, as identified in the semantic segmentation module (SEMSEG). The image segmentation module (IMSEG) effectively divides the architectural floorplan image into the at least one region based on the classified pixels of the plurality of pixels (e.g., classified as a class of region boundaries or a class of region areas). The image segmentation module is generally implemented using image processing techniques on the region-boundary segmentation to divide the floorplan image into various regions.

In an embodiment such as shown in FIG. 2, the architectural floor plan image is input into the semantic segmentation module (SEMSEG) of the segmentation module (SEGMT). The semantic segmentation module (SEMSEG) classifies each pixel in the floorplan document into one of the classes of region boundaries or one of the classes of region areas. The image segmentation module (IMSEG) then divides the floorplan document into at least one region based on the classified pixels. The at least one region defined by the segmentation model is then provided to the label determination module, together with the object data from the object detector and the text data from the text analyzer.

Various configurations of the segmentation module are provided in the system of the present disclosure.

In an embodiment, the image segmentation module (IMSEG) is configurable to utilize one or more suitable image processing techniques (e.g., Watershed, K-means) to divide the floorplan image into regions based on the boundary segmentation.

In an embodiment, the semantic segmentation module includes a neural network, and the neural network is made up of modules that include at least one of an encoder, a region-boundary decoder, a region-area decoder, and a classifier for multiclass semantic segmentation.

In an additional embodiment, the neural network of the semantic segmentation module is a trainable CNN, where the various weights of the modules in the CNN can be updated (during training) to minimize an overall loss function of the whole network defined by the CNN.

Various suitable structures of neural network for the semantic segmentation module can be implemented within the segmentation module as disclosed herein.

In at least some embodiments, the neural network is configurable as a multi-task network that has an encoder module to extract hierarchical features from the architectural floorplan image. In additional embodiments, the semantic segmentation module can also include at least one decoder for the hierarchical features from the encoder. The at least one decoder can include, for example, a room boundary decoder (RBD) and a room type decoder (RTD) to recognize the room-boundary and room-type pixels, respectively, within the encoded hierarchical features.

In another additional embodiment, the semantic segmentation module also includes an attention model (AM) which is configurable to refine the room type pixels by suppressing the noises near the room boundaries.

In an example embodiment, the segmentation module (SEGMT) is implemented using a U-Net architecture with an encoder-decoder structure, and the image segmentation module (IMSEG) is implemented using at least one of a watershed algorithm and a graph-based segmentation technique. In this embodiment, the semantic segmentation module (SEMSEG) may utilize a combination of cross-entropy loss and dice loss to improve segmentation accuracy, and the image segmentation module (IMSEG) can employ the watershed algorithm and/or the graph-based segmentation technique to divide the floor plan into the at least one region based on the semantic segmentation results such that the at least one region is a distinct region.

### Specific Embodiments of the Segmentation Module Architecture

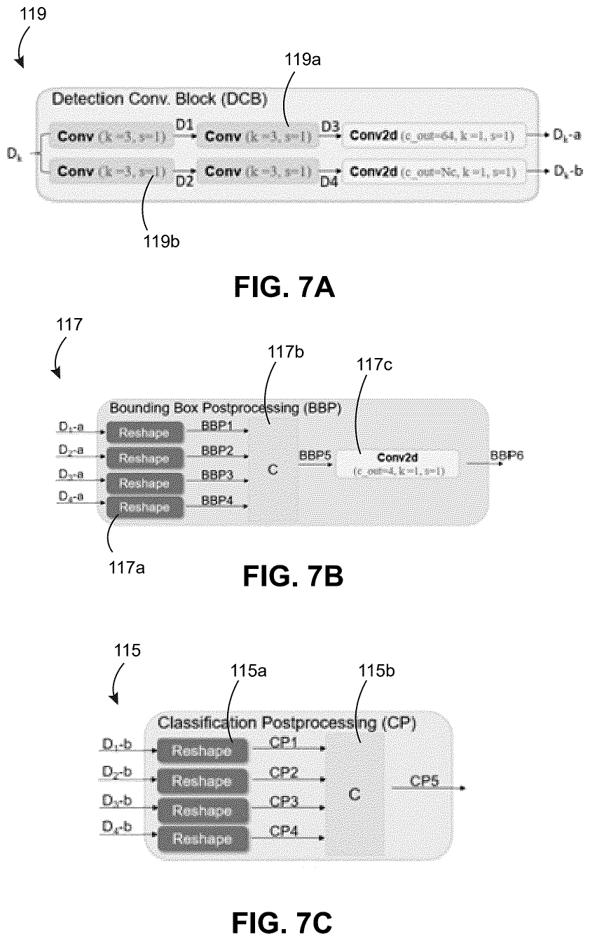

Referring to FIG. 8, there is provided an exemplary block diagram of an embodiment of the segmentation module (which, in this embodiment, may be referred to as FloorNet) for semantic segmentation of the architectural floorplan image. As illustrated in this block diagram and described above, the segmentation module includes at least the semantic segmentation module and the image segmentation module.

In the specific embodiment provided in FIG. 8, the semantic segmentation module 130 is the segmentation module 130a, and is structured to take in an input architectural floorplan image 101, and to process the image 101 within five modules that include a CNN encoder module 410, two decoder modules 420 (a room type decoder module 422, a room boundary decoder module 424), a multiscale room boundary attention model (MRBAM) module 430, and a floor classification (FC) module 440. The encoder module 410 is configurable to extract hierarchical features (E1-E5) from the architectural floorplan image 101, and these hierarchical features (E1-E5) are processed by the room boundary decoder (RBD) module 424 and the room type decoder (RTD) module 422, in parallel, to recognize the room-boundary and room-type pixels, respectively. The multiscale room boundary attention model (MRBAM) module 430 of the segmentation module 130 can be applied to combine features from the RBD and RTD modules 422, 424 to refine the semantic segmentation, and refine the room type pixels (e.g., by suppressing the noises near the room boundaries). The FC module 440 can then predict the final segmentation result, outputting a set of feature maps 401 (e.g., C1, C2, and C3).

In an additional embodiment, the encoder module 410 is configurable to generate feature maps of the detected features within the floorplan image, and the encoder 410 module includes a deep backbone to efficiently extract the feature maps. The feature maps which are output by the encoder 410 are passed onto the two decoders (e.g., the room boundary prediction and the room type prediction) 420, and each feature map is shared by at least two simultaneous branches of the two decoders 420.

Various examples of suitable deep backbones for the encoder module include, but are not limited to, VGG16, ResNet34 and DenseNet121. Example 11 in the present disclosure details exemplary CNN encoder modules which include encoder backbones based on each of VGG16, ResNet34 and DenseNet121, respectively. Example 11 also presents the resulting performance of the CNN encoder modules that utilize each of the aforementioned deep backbone structures.

In the embodiment provided in FIG. 8 an exemplary CNN encoder module is illustrated, and the CNN encoder module includes at least 5 convolution blocks, and generates at least five feature maps (including at least E1-E5). The CNN encoder shown in this embodiment may generate the feature maps from the architectural floor plan image, which can then be used by the next modules in the semantic segmentation module.

The decoder modules of semantic segmentation module generally take in and process feature maps from CNN encoder. As described above, some embodiments of decoder module include at least the room boundary decoder (RBD) module and the room type decoder (RTD) module. These specific decoder modules can be configurable such that after the feature maps (e.g., the features maps of E1-E5) are extracted by the CNN encoder, the room boundary decoder module uses these features in the maps to predict the room boundaries and to generate additional feature maps for the room type decoder module. A function of the room type decoder is to predict the room type.

In at least some embodiments of the decoder modules, the room boundary decoder (RBD) module and room type decoder (RTD) module utilize a linear interpolation upsampling method.

In an alternate embodiment of the decoder modules, the room boundary decoder (RBD) module and room type decoder (RTD) module utilize an upconvolution method. The learning process of the upconvolution may be able to recover more spatial details compared to the linear interpolation methods.

The decoder modules are also configurable to output features maps, where the feature maps will be modified maps based on the feature maps provided to the decoder modules from the encoder module. Generally, the feature maps output from the decoder modules can be passed to the attention module or can be passed to the floor classification module (FC) for classifying the pixels into either a class of the plurality of classes of region boundaries or a class of the plurality of classes of region areas.

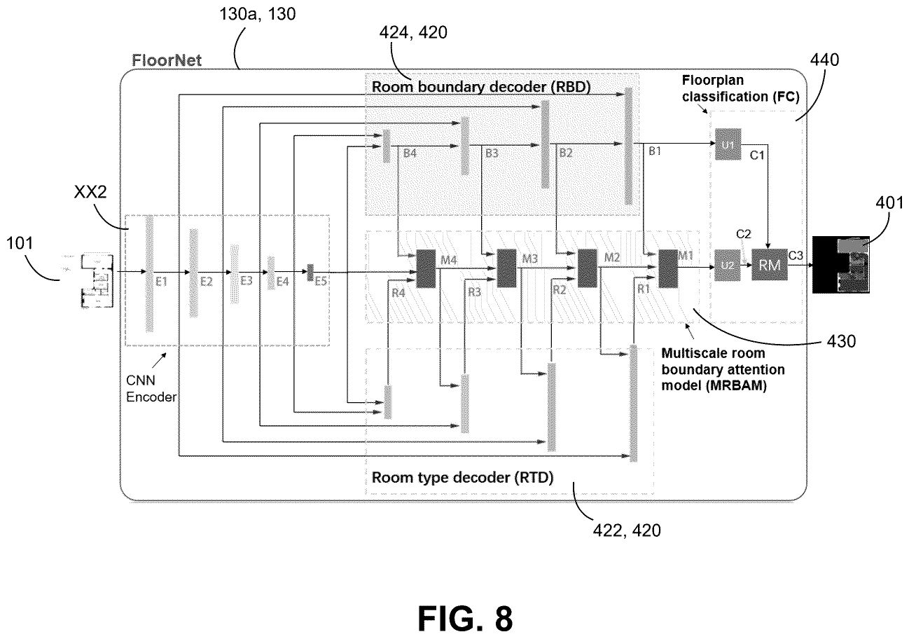

In the specific embodiment provided in FIG. 9A, a schematic of one embodiment of the room boundary decoder module 424 is provided. This schematic shows one units 424a of the RBD module 424, where the RBD module 424 can include one or more units. The illustrated unit of the RBD module 424 receives two inputs: Feature 1 (2N×2N×C1) and Feature 2 (N×N×C2). Feature 1 is processed through a Conv2d module 424b (k=3, s=1). Feature 2 is processed through an UpConv2d module 424c (k=4, s=2). The outputs of these two modules are added together. The result of this addition is then processed through another Conv2d module 424d (k=3, s=1) followed by a Batch Normalization (BN) layer 424e to produce the output feature map (2N×2N×Co). Feature-1 input refers to the features coming from the CNN encoder (e.g., feature maps E1, E2, E3, E4) and Feature-2 input refers to the intermediate learned features (B4, B3, B2) coming from the preceding RBD unit (except for the first RBD unit for which Feature-2 is the feature map E5 from the CNN encoder). The size of the exemplary RBD unit feature maps B1-B4 described in Example 10 of the present disclosure.

In the embodiment in FIG. 9A, the “+” means elementwise addition. C₂ equals K2C₁ for the B4 layer and C₁ for the other layers in the decoder. C₀ equals C₁ for the B4 layer and C_{1/2} for the other layers in the decoder. BN means batch normalization. (k, s) refers to (kernel size, stride value). The size of Feature 2 of an RBD unit is half (in both directions) the size of Feature-1. Therefore, Feature-2 is upsampled before the addition with the convolution output of Feature-1. The summation of filtered Feature-1 and upsampled Feature-2 goes through another convolution layer to learn the features, and a batch normalization layer (denoted as “BN”) is used to stabilize the learning process. In this embodiment, the term “UpConv2D” means the upconvolution with filters of size 4×4.

In at least some embodiments, the architecture of the RTD is similar to the RBD and may include a corresponding number of RTD units to a number of RTD units included in the semantic segmentation module. The configuration of the RTD module may, for example, be similar to that of the RBD module shown in FIG. 9A. However, unlike the RBD module, the bottom input of a RTD module (as shown in FIG. 8) would come from the CNN encoder and the top input would come from the preceding attention module (except for the first RTD unit for which the top input would come from the CNN encoder).

In at least some embodiments of the segmentation module described herein, the module includes various enhancements to different modules of a foundational BAAM-CNN (Boundary-Aware Attention Mechanism-Convolutional Neural Network) architecture. These enhancements include modifications to the CNN Encoder, the RBD (Room Boundary Detection) module, the RTD (Room Type Detection) module, and the attention module. As shown in Example 13, an ablation study conducted using the specific embodiment of the segmentation module shown in FIG. 8 demonstrated an improvement performance in the modified segmentation module, showing that the mean Intersection over Union (mloU) of the network may be enhanced with the introduction of the new encoder, improved decoders, and the refined attention module.

In an embodiment, the MRBAM combines room boundary features from the feature maps output from the RBD module with room type features from the features maps output from the RTD module and may combine the room boundary features and room type features at different scales. The MRBAM may also be configurable to combine the RBD and RTD features and perform further semantic segmentation (i.e., to predict the room type of each pixel). The MRBAM efficiently combines the room boundary features and the room type features across different scales. Each MRBAM sub-module is configurable to utilize well-predicted room boundary features to fine-tune the room type features. The refined feature outputs of a given MRBAM sub-module are then passed to a subsequent convolutional layer, through which the room type prediction is further improved.

In an additional embodiment, the MRBAM includes a plurality of MRBAM sub-modules, where each MRBAM sub-modules uses the well-predicted room boundary features to fine tune the room type features. The learned feature of a MRBAM sub-modules is passed to the next-level convolution layer, through which the room type prediction is improved within the attention module. In the example experiments, the proposed technique is evaluated using two types (SBT and CAT) of floor plan images. Experimental results, such as those provided in Example 12 of the present disclosure, have shown that the proposed technique can achieve a superior performance compared to the state-of-the-art methods for both floor plan types.

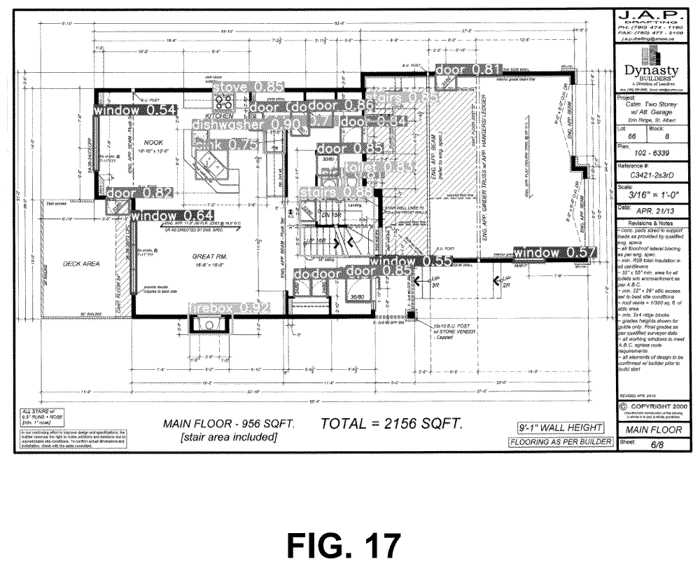

In the specific embodiment shown in FIG. 8, the MRBAM 430 has four identical sub-modules (labelled M1 to M4). Each MRBAM sub-modules takes the feature maps from the room boundary and room type decoder nodules 422, 424 as inputs. There are four different levels in the MRBAM 430 that processes the room boundary features and room type features at different scales. FIGS. 17A and 17B provide details on the logic and internal structure of the MRBAM 430 in the segmentation module 130.

In the specific embodiment shown in FIGS. 9B and 9C, each MRBAM sub-module of the MRBAM 430 has three inputs. Within the MRBAM sub-module, the three inputs (Tb, Tₚ, Tᵣ) pass through several modules (e.g., Conv Unit shown in FIG. 9C) and are finally concatenated at the Concat module. The three inputs include a top input (Tb) that is the room boundary feature maps coming from a room-boundary decoder 422, a bottom input (Tᵣ) that is the room type feature maps from a room-type decoder 424, and a middle input (Tₚ) that is the intermediate feature maps coming from the preceding MRBAM sub-modules (for the first MRBAM sub-modules this input comes from the CNN encoder 410). T_{b} is the room-boundary feature, Tₚ is the output feature of the preceding MRBAM unit, and Tᵣ is the room-type feature. N is the number of features (which is 1 in this work). The weights w₁, w₂, w₃, w₄ and w₅ are applied on the five feature maps before the concatenation operation.

Within the data that is passed from the MRBAM sub-modules to the Concat module, there are a plurality of inputs to the Concat module. In at least some embodiments such as shown in FIG. 9B, the Contact module is structure to produces an output T_{c}(N, W, H, 5C) where Nis the number, W is the width, H is the height, and C is the number of channels for the output. An exemplary embodiment that details the plurality of inputs to the Contact module is provided in Example 9 of the present disclosure.

In another additional embodiment, the MRBAM within the semantic segmentation module is further configurable to incorporate channel contextual information (CCI). While initial iterations of the MRBAM may operate without explicitly considering contextual information among channels, integrating CCI information may improve the semantic segmentation performance of the MRBAM. Accordingly, some embodiments of the MRBAM may include an efficient CCI module is provided to fine-tune the feature maps output from the CNN Encoder, thereby leveraging inter-channel dependencies to enhance the overall accuracy of the semantic segmentation.

As provided above, the semantic segmentation module may include the FC module, which can receive feature maps from the decoder modules and or the attention module (e.g., the MRBAM). The FC module is generally configurable to predict a floorplan semantic segmentation result based on feature maps received from the decoder modules (i.e., the RBD, RTD decoder modules) and/or the attention module.

In at least some embodiments, the FC module is structured such that within the module, input feature maps B1 and M1 are processed through respective U-modules, yielding outputs C1 and C2. C1 and C2 represent probability values for different pixel classes within the floor plan. Specifically, C1 provides probability values for {background, wall, door/window} classes for each pixel location. C2, on the other hand, provides probability values for a set of additional classes, such as 7 classes for an R3D dataset or 9 classes for a CAFP dataset, for each pixel location. It is noted that C2 does not provide probabilities for window/door or wall classes, as these probabilities are provided by C1. Details of an example embodiment of the FC module are provided in Example 10 of the present disclosure.

In at least some additional embodiments, the FC module may further comprise an RM module. The RM module may be configurable to process the initial probability outputs, such as C1 and C2, from the FC module and to refine and consolidate the pixel-level classification. Broadly, the RM module operates by evaluating the preliminary class probabilities for each pixel and applying a set of rules or a logical framework to resolve ambiguities and produce a definitive semantic label for each pixel, thereby generating the final semantic segmentation map.

The RM module combines the C1 and C2 outputs from the FC module and generate the final semantic segmentation result for each pixel at an (x, y) location. This combination process involves, for a given pixel at location (x, y), first evaluating the C1 values. If the pixel is classified as a door/window or a wall based on the C1 values, the pixel is accordingly classified as a door/window or wall. However, if the pixel is classified as background based on the C1 values, the final classification of the pixel is then determined by evaluating the C2 values for that same pixel location.

### Semantic Labeler

In at least some embodiments, the semantic labeling module (LBLDET) employs a hierarchical logic to assign semantic labels to each region. The semantic labeler may consider inferences from some or all of the object detector (OBJDET), text analyzer (TXTANL), and segmentation module (SEMSEG) to label regions generated from the image segmentation module (IMSEG).

In at least some additional embodiments, the semantic labeling module (LBLDET) is configurable to prioritize text data when assigning semantic labels, which may provide a more accurate and reliable interpretation of the architectural floorplan.

In one such embodiment, the semantic labeler is configurable to take in information from the three other modules of the system, and to process the information for determining the semantic label for each region of the at least one region by: i) determining if at least a subset of the text data from the architectural floor plan image is associated with the region; wherein when the subset of the text data is associated with the region, the label of the region is generated based on the subset of the text data; and wherein when the subset of the text data is not associated with the region, the label of the region is at least one of i) a label that is inferred from the plurality of detected and classified objects, and ii) a label that is determined by the label of a maximum classified region-area pixels.

Said another way, the semantic labeler first determines if at least a subset of the text data from the architectural floor plan image is associated with a given region. When such text data is associated with the region, the label for that region is generated based on this text, as it is considered a primary indicator of the region's class. (e.g., if a region from IMSEG has associated text data from TXTANL, the region label is determined by said text data). However, if none of the text data is associated with the region, the semantic labeler then determines the label in one of two ways: either semantic labeler infers a label from the object data (e.g., from the plurality of detected and classified objects within the region), or the semantic labeler assigns a label that corresponds to the maximum classified region-area pixels. Effectively, if a region from IMSEG has no associated text data from TXTANL but has objects from OBJDET, the region label may be inferred by the objects based on predefined rules. If the region has an object not covered by predefined rules, the region label is determined by the label of the maximum classified region-area pixels from the SEMSEG, while if a region from IMSEG has no associated text data or objects, the region label is determined by the label of the maximum classified region-area pixels from the SEMSEG.

The maximum classified region-area pixels is effectively the pixel class (e.g., ‘bedroom,’ ‘kitchen’) that covers the largest area within the region, as determined by the segmentation module. For example, if a region primarily consists of pixels classified as ‘bedroom’ by the segmentation module, the semantic labeler will assign ‘bedroom’ as the label for that region. This effectively provides a fallback mechanism based on pixel-level classification as determined in the segmentation module (SEG).

The maximum classified region-area pixels approach leverages the output of the SEMSEG, which classifies each pixel within the floor plan image into predefined categories, such as ‘room,’ ‘wall,’ or ‘door.’ To determine the most appropriate label for a region, the semantic labeler analyzes the pixel-level classifications within that region and identifies the class that is assigned to the maximum number of pixels. For example, if a particular region predominantly contains ‘bedroom’ pixels according to the SEMSEG, the semantic labeler will assign the ‘bedroom’ label to that region. This approach provides a robust and reliable method for labeling regions even in the absence of explicit textual or object-based cues. The classes used for determining maximum classified region-area pixels are configurable according to each specific application, allowing for high-level or low-level abstraction of regions.

In additional embodiments, the determination of the semantic label for each region may also consider the geometric relationships between the detected objects and the locations of the textual content.

While these steps for the operation of the semantic labeler are provided for considering the inferences from some or all of the object detector (OBJDET), text analyzer (TXTANL), and segmentation module (SEMSEG) when labeling images from the image segmentation module (IMSEG), other suitable steps and processes for considering such inferences may be applied within the semantic labeler.

While the above description contains many specifics, these specifics should not be construed as limitations of the present disclosure, but merely as exemplifications of preferred embodiments thereof. Those skilled in the art will envision many other embodiments within the scope and spirit of the present disclosure as defined by the claims appended hereto.

The following examples are illustrative of several embodiments of the present technology:

Embodiment 1. A system for processing an input architectural floor plan image, the system comprising a computer processor and a non-transitory computer-readable medium comprising one or more sequences of instructions for detecting objects in a floor plan using a neural network, the system comprising: an object detector comprising a first set of sequences executed by the computer processor to at least detect and classify a plurality of objects in an architectural floor plan image to output object data; a text analyzer comprising a second set of sequences executed by the computer processor to at least identify and extract text from the architectural floor plan image to output machine-readable text data; a segmentation module comprising a third set of sequences executed by the computer processor to at least divide the architectural floor plan image into at least one region; and a semantic labeler comprising a fourth set of sequences executed by the computer processor to at least determine a semantic label for each region of the at least one region based, at least in part, on the object data and the text data from the architectural floor plan image; wherein the system quantifies building parameters of the at least one region based on the semantic label of the at least one region for generating a structured, machine-interpretable representation of the architectural floorplan.

Embodiment 2. The system of embodiment 1, wherein the object data includes object classes and object locations for the plurality of objects within the architectural floor plan image, and wherein the machine-readable text data includes textual content and textual content locations within the architectural floor plan image.

Embodiment 3. The system of embodiment 1 or 2, wherein the building parameters of the at least one region form a structured, machine-interpretable digital model of the architectural floorplan; and wherein the model is structured to enhance the computer processor functional capabilities for automated architectural analysis by transforming unstructured data in the architectural floorplan image into structured machine-interpretable design data for downstream processes.

Embodiment 4. The system of any one of embodiments 1 to 3, wherein the system is configurable to utilize the determined building parameters for at least one of: generating a building information model (BIM), estimating construction costs, and verifying building code compliance.

Embodiment 5. The system of any one of embodiments 1 to 4, wherein the system is configurable to output the building parameters to a user interface, and to generate a Bill of Materials report based at least on the determined building parameters for each semantically labelled region, the report being formatted for automated input into an architectural design or construction management software system.

Embodiment 6. The system of any one of embodiments 1 to 5, wherein the object detector, the text analyzer, and the segmentation module are configurable to operate in parallel.

Embodiment 7. The system of any one of embodiments 1 to 6, wherein the object detector is configurable to apply a neural network (such as a CNN) for outputting the object data of the plurality of objects.

Embodiment 8. The system of embodiment 7, wherein the neural network comprises: a backbone module configurable to analyze the architectural floor plan image to generate a set of floorplan feature maps; a mid-level processing (MLP) module configurable to learn from and tune the set of floorplan feature maps for generating an enhanced set of floorplan feature maps; and a detection module configurable to classify the plurality of objects based on the enhanced set of floorplan feature maps from the MLP module.

Embodiment 9. The system of embodiment 8, wherein the backbone module comprises a series of convolution layers and pooling layers that generate feature maps.

Embodiment 10. The system of embodiment 7, wherein the detection module comprises a plurality of detection heads configurable to operate independently for localizing and classifying the plurality of objects; wherein at least one of the plurality of detection heads is specifically adapted to detect small-sized objects, thereby expanding inputs of contextual information, increasing a number of candidate proposals, and improving detection performance on small-size objects within the architectural floor plan image.

Embodiment 11. The system of embodiment 8, wherein the detection module is further configurable to utilize rectangular bounding boxes for identifying and classifying the object data for the plurality of objects by predicting a location and size of the rectangular bounding boxes during classification of the plurality of objects.

Embodiment 12. The system of embodiment 8 or 11, wherein the detection module is further structured for executing an object detection process that includes: receiving the enhanced set of floorplan feature maps from the MLP module; and processing the enhanced set of floorplan feature maps through a plurality of detection convolution blocks for determining the bounding boxes and classifications for the plurality of objects within the architectural floor plan image.

Embodiment 13. The system of embodiment 12, wherein the plurality of detection convolution blocks include at least a bounding box postprocessing (BBP) block and a classification postprocessing (CP) block.

Embodiment 14. The system of any one of embodiments 7 to 13, wherein the set of feature maps generated by the backbone module includes at least four feature maps with multi-scale information for the floorplan features.

Embodiment 15. The system of embodiment 14, wherein the detection module is configurable to process the enhanced set of floorplan feature maps on at least four parallel processing paths that correspond to the at least four feature maps generated by the backbone module.

Embodiment 16. The system of any one of embodiments 7 to 14, wherein the MLP module includes at least one attention mechanism for tuning the floorplan feature maps to generate the enhanced set of floorplan feature maps, the at least one attention mechanism having a plurality of processing stages that each generate a unique feature map of the enhanced floorplan features.

Embodiment 17. The system of embodiment 14, wherein the at least one attention mechanism includes an Attention-gated Convolutional Block Attention Module (AC-CBAM) that is configurable to direct the object detector to advantageous features that are beneficial for object detection.

Embodiment 18. The system of embodiment 17, wherein the AC-CBAM comprises a CBAM attention mechanism that is integrated with first and second C2f modules; wherein the CBAM attention mechanism suppress invalid features learned from the first C2f module; wherein the second C2f module retunes the advantageous features.

Embodiment 19. The system of any one of embodiments 1 to 18, wherein the text analyzer comprises: a text character recognition component configurable to recognize text characters within the architectural floor plan image to generate the text data; and an error correction and parsing component configurable to perform error corrections on the text characters of the text data such that the text data generated from the text analyzer includes a plurality of recognizable strings.

Embodiment 20. The system of embodiment 19, wherein the text character recognition component is configurable to use a CNN-based OCR technique; and wherein the error correction and parsing component is configurable to use a natural language processing (NLP) technique.

Embodiment 21. The system of any one of embodiments 1 to 20, wherein the segmentation module comprises: a semantic segmentation component configurable to classify each pixel of a plurality of pixels that form the architectural floor plan image into one of a plurality of classes of region boundaries or one of a plurality of classes of region areas; and an image segmentation component configurable to divide the architectural floor plan image into at least one region based on the plurality of classes of region boundaries and the plurality of classes of region areas for the plurality of pixels in the architectural floor plan image.

Embodiment 22. The system of embodiment 21, wherein the semantic segmentation component is configurable to utilize a CNN, the CNN including an encoder, a region-boundary decoder, a region-area decoder, and a multiclass semantic segmentation classifier.

Embodiment 23. The system of embodiment 22, wherein the encoder of the CNN is configurable to generate output feature maps.

Embodiment 24. The system of embodiment 23, wherein the region-boundary decoder and the region-area decoder include at least two simultaneous branches configurable to share the output feature maps of the encoder, the branches including at least a room boundary prediction branch and a room type prediction branch.

Embodiment 25. The system of any one of embodiments 22 to 24, wherein the CNN further includes at least one Multi-Resolution Boundary Attention Module (MRBAM) unit configurable to combine room boundary features and room type features at different scales.

Embodiment 26. The system of embodiment 25, wherein the at least one MRBAM unit is configurable to use predicted room boundary features to fine-tune room type features and wherein learned features of the at least one MRBAM unit are passed to a next-level convolution layer to improve room type prediction via an attention mechanism.

Embodiment 27. The system of any one of embodiments 22 to 26, wherein the multiclass semantic segmentation classifier is a floorplan classifier module that is configurable to receive feature maps from the region-boundary decoder module, the region-area decoder module, and the MRBAM to generate a set of first output values representing probability values for background object classes, and a set of second output values representing probability values for a plurality of additional classes which are not included in the background object classes.

Embodiment 28. The system of embodiment 27, wherein the feature maps include at least first and second feature input maps, and wherein the floorplan classifier module includes a plurality of U-modules for generating the set of first output values and the set of second output values from the first and second feature input maps, respectively.

Embodiment 29. The system of any one of embodiments 1 to 28, further comprising a label determination module configurable to determine the semantic label for each region of the at least one region by: determining if at least a subset of the text data from the architectural floor plan image is associated with the region; wherein when the subset of the text data is associated with the region, the label of the region is generated based on the subset of the text data; and wherein when the subset of the text data is not associated with the region, the label of the region is at least one of i) a label that is inferred from the plurality of detected and classified objects, and ii) a label that is determined by the label of a maximum classified region-area pixels.

Embodiment 30. The system of embodiment 7, wherein the backbone module comprises a CNN selected from the group consisting of: VGG16, ResNet, and DenseNet.

Embodiment 31. The system of embodiment 19, wherein the error correction and parsing component is configurable to utilize a technique selected from the group consisting of: a beam search algorithm and a language model.

Embodiment 32. The system of any one of embodiments 1 to 31, wherein the object detector is configurable to perform pre-processing on the architectural floor plan images, the pre-processing comprising: dividing the plurality of architectural floor plan images into at least a training dataset, a validation dataset, and a testing dataset; annotating each image within at least the training dataset and the validation dataset to generate corresponding ground-truth annotation data; applying at least one data augmentation technique to images in at least the training dataset and the validation dataset; resizing the augmented images to a predetermined input dimension suitable for processing by a deep learning model; and resizing detection results obtained from the deep learning model back to an original dimension of the architectural floor plan images for visualization.

Embodiment 33. The system of embodiment 32, wherein the annotation data includes at least locations and classes of objects within each image; and wherein the at least one data augmentation technique comprises at least rotation and flipping of the images, thereby expanding the size of the training and validation datasets.

Embodiment 34. A computer-implemented method for processing an input architectural floor plan image to determine building parameters for the architectural floor plan, the method comprising: performing at least one object detection step on the architectural floor plan image for detecting and classifying a plurality of objects in the architectural floor plan image to output object data, the object data including object classes and object locations for the plurality of objects within the architectural floor plan image, performing at least one text analysis step for identifying and extracting text from the architectural floor plan image to output text data, the text data including textual content and textual content locations within the architectural floor plan image, performing at least one segmentation step for dividing the architectural floor plan image into at least one region, determining a semantic label for each region of the at least one region based, at least in part, on the object data and the text data, and quantifying the building parameters of the at least one region based on the semantic label of the at least one region.

Embodiment 35. The method of embodiment 34, further comprises generating a Bill of Materials report based at least on the determined building parameters for each semantically labeled region, the report being formatted for automated input into an architectural design or construction management software system.

Embodiment 36. The method of embodiment 34 or 36, further comprising outputting the building parameters to a user interface and utilizing the determined building parameters for at least one of: generating a building information model (BIM), estimating construction costs, and verifying building code compliance.

Embodiment 37. The method of any one of embodiments 34 to 36, wherein the at least one object detection step, the at least one text analysis step, and the at least one segmentation step are done in parallel.

Embodiment 38. The method of any one of embodiments 34 to 37, wherein the at least one object detection step for outputting the object data of the plurality of objects includes applying a neural network (such as a convolutional neural network (CNN)).

Embodiment 39. The method of embodiment 38, wherein the neural network comprises: a backbone module for analyzing the architectural floor plan image to generate a set of floorplan feature maps, a mid-level processing (MLP) module for learning from and tuning the set of floorplan feature maps for generating an enhanced set of floorplan feature maps, and a detection module for classifying the plurality of objects based on the enhanced set of floorplan feature maps from the MLP module.

Embodiment 40. The method of embodiment 39, wherein the detection module utilizes rectangular bounding boxes for identifying and classifying the object data for the plurality of objects by predicting a location and size of the rectangular bounding boxes during classification of the plurality of objects.

Embodiment 41. The method of embodiment 39 or 40, wherein the detection module is structured for executing an object detection process that includes: receiving the enhanced set of floorplan feature maps from the MLP module; and processing the enhanced set of floorplan feature maps through a plurality of detection convolution blocks for determining the bounding boxes and classifications for the plurality of objects within the architectural floor plan image.

Embodiment 42. The method of embodiment 41, wherein the plurality of detection convolution blocks include at least a bounding box postprocessing (BBP) block and a classification postprocessing (CP) block.

Embodiment 43. The method of embodiment 42, wherein the detection module further includes a Non-Maximum Suppression (NMS) that is applied to an output of the plurality of detection convolution blocks.

Embodiment 44. The method of any one of embodiments 39 to 43, wherein the set of feature maps generated by the backbone module includes at least four feature maps with multi-scale information for the floorplan features.

Embodiment 45. The method of embodiment 44, wherein the detection module processes the enhanced set of floorplan feature maps on at least four parallel processing paths that correspond to the at least four feature maps.

Embodiment 46. The method of any one of embodiments 39 to 45, wherein the MLP module includes at least one attention mechanism for tuning the floorplan feature maps to generate the enhanced set of floorplan feature maps.

Embodiment 47. The method of any one of embodiments 34 to 46, wherein the at least one text analysis step comprises: a text character recognition step for recognizing text characters within the architectural floor plan image to generate the text data; and an error correction and parsing step to perform error corrections on the text characters of the text data such that the text data generated from the at least one text analysis step includes a plurality of recognizable strings.

Embodiment 48. The method of embodiment 47, wherein the text character recognition step uses a CNN-based OCR technique; and wherein the error correction and parsing step uses a natural language processing (NLP) technique.

Embodiment 49. The method of any one of embodiments 34 to 48, wherein the at least one segmentation step comprises: a semantic segmentation step for classifying each pixel of the plurality of pixels that form the architectural floor plan image into one of a plurality of classes of region boundaries or one of a plurality of classes of region areas; and an image segmentation step for dividing the architectural floor plan image into at least one region based on the plurality of classes of region boundaries and the plurality of classes of region areas for the plurality of pixels in the architectural floor plan image.

Embodiment 50. The method of embodiment 49, wherein the semantic segmentation step utilizes a CNN that includes an encoder, a region-boundary decoder, a region-area decoder, and a classifier for multiclass semantic segmentation.

Embodiment 51. The method of any one of embodiments 34 to 50, wherein determining the semantic label for each region of the at least one region comprises: determining if at least a subset of the text data is associated with the region; wherein when the subset of the text data is associated with the region, the label of the region is generated based on the subset of the text data; and wherein when the subset of the text data is not associated with the region, the label of the region is at least one of i) a label that is inferred from the plurality of detected and classified objects, and ii) a label that is determined by the label of a maximum classified region-area pixels.

A more complete understanding can be obtained by reference to the following specific Examples. These Examples are described solely for purposes of illustration and are not intended to limit the scope of the invention. Changes in form and substitution of equivalents are contemplated as circumstances may suggest or render expedient. Without further description, it is believed that one of ordinary skill in the art can, using the preceding description and the following illustrative examples, make and utilize the constructs of the present disclosure and practice the claimed processes and/or systems. The following working examples, therefore, specifically point out the typical aspects of the present invention and are not to be construed as limiting in any way in the remainder of the disclosure. Although specific terms have been employed herein, such terms are intended in a descriptive sense and not for purposes of limitation.

### EXAMPLES

### Example 1—Example Dataset

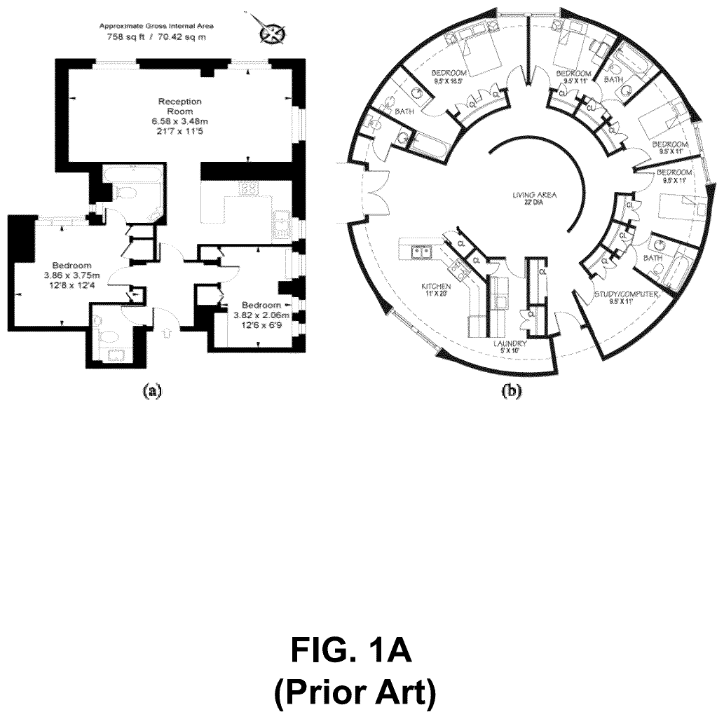

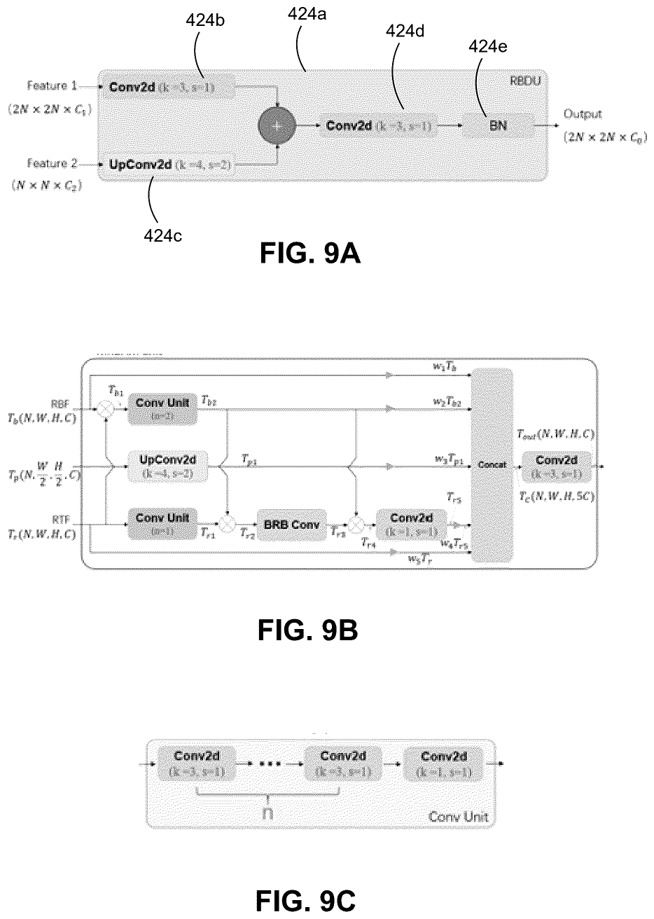

In the present disclosure, two non-limiting, example datasets were used to evaluate the performance of the proposed technique: (1) the R3D dataset and (2) the complex architecture type floor plan (CAFP) dataset. FIG. 10 shows an image example from the R3D dataset and FIG. 1B shows an image from the CAFP dataset. Both datasets have pixel-wise ground truth labels for floor plan training, validation and testing. The R3D dataset has 232 images, each of size 512×512 pixels. In the CAFP dataset, a total of 80 floor plan images, each of size 3400×2200 pixels, have been obtained from the local house builder collaborators and are manually annotated to generate pixel-wise ground truth images.

TABLE 1
The dataset for performance evaluation
and the classification categories:

| | | CAFP |
|---|---|---|
| | R3D | (Augmented) |
| Number of | 160 | 416 |
| training images | | |
| Number of | 19 | 96 |
| validation images | | |
| Number of | 53 | 128 |
| testing images | | |
| Total number | 232 | 640 |
| of images | | |
| Classification | 9 categories | 11 categories |
| categories | background | background |
| | closet | closet |
| | washroom | washroom |
| | LKD* room | LKD* room |
| | hall | hall |
| | bedroom | bedroom |
| | window/door | window/door |
| | wall | wall |
| | balcony | laundry |
| | | garage |
| | | stairs |

*LKD refers to living-room/kitchen/dining-room.

The CAFP dataset is expanded eight times by use of augmentation: (i) original, (ii) rotation of original image by 90°, 180° and 270°, and (iii) up-down flipping of 4 images from (i) and (ii). The augmented CAFP dataset includes 640 images and is used in the performance analysis of the systems and modules as described in the present disclosure.

### Example 2—Data Preprocessing

An example of the data preprocessing module for the data preprocessing step is shown in the schematic of FIG. 3, where the example preprocessed dataset is the CAFP dataset described above in Example 1. For the fifty-four-floorplan image dataset, the example dataset was divided into a training dataset with 36 images, a validation dataset with 8 images, and a testing dataset with 10 images. Each floor plan image was annotated to generate a .txt file (or similar file type) that contains the locations/sizes of all bounding boxes and the objects classes. Augmentation was used to expand the dataset in the manner that first rotates a floorplan image by, as an example, 90°, 180° and 270°, and the four rotated images were then flipped based on the horizontal center line. After augmentation, there were 288 floorplan images in the training dataset, 64 floorplan images in the validation dataset and 80 floorplan images in the testing dataset. Note that all the images in the dataset were resized to 640×640×3 before feeding them to the ArchNetv2 and the predicted detection results were resized back to 2200×3400 for visualization.

### Example 2—Feature Maps Output from Embodiment of the Backbone Module

The following example provides details of the feature maps for the modules shown in FIGS. 5A and 5B. FIGS. 5A and 5B illustrate exemplary embodiments of a C2f module, which is a core component within the architecture. Each C2f module comprises at least two Conv modules (each utilizing 1×1 convolutions) and a configurable number, “n”, of bottleneck modules. Each bottleneck module itself integrates two additional Conv modules (with a kernel size of 3×3 and a stride value of 1 for both) and a skip connection. These bottleneck modules are strategically employed to enhance feature extraction capabilities and improve the training convergence of the network. In these specific examples, the input feature maps maintain the same spatial dimensions as the output of the bottleneck module, ensuring consistent resolution. The hyperparameter “n”, depicted in FIG. 4, is carefully selected and optimized to achieve the best possible performance for the specific application.

An exemplary spatial pyramid pooling fast (SPPF) module is used at the end of the backbone module to pool and concatenate the multiscale region features so that the network learns the object features more comprehensively. This SPPF module is configurable to efficiently pool and concatenate multiscale regional features.

An exemplary set of feature maps generated using the embodiment of the modules shown in FIGS. 5A and 5B is presented below in Table 2. Table 2 shows the sizes of the feature maps, labeled B1 through B10, within the backbone module, assuming an input image size of 640×640×3 pixels. In Table 2, “Nc” represents the total number of classes, which is specifically set to 13 in the exemplary embodiments provided in the present disclosure. This consistent input size and class count ensure a standardized evaluation and operation of the system.

TABLE 2
Sizes of feature maps in FIG. 4 for input size of 640 ×
640 × 3. Note M = 160, 80, 40, 20 for Path1, Path2,
Path3, Path4, respectively, in the example detection module.

| Feature | Size | Feature | Size |
|---|---|---|---|
| B1 | 320 × 320 × 64 | N1 | 40 × 40 × 512 |
| B2 | 160 × 160 × 128 | N2 | 80 × 80 × 256 |
| B3 | 160 × 160 × 128 | N3 | 160 × 160 × 128 |
| B4 | 80 × 80 × 256 | N4 | 80 × 80 × 256 |
| B5 | 80 × 80 × 256 | N5 | 40 × 40 × 512 |
| B6 | 40 × 40 × 512 | N6 | 20 × 20 × 512 |
| B7 | 40 × 40 × 512 | D₁-a, D₂-a, | M × M × 64 |
| | | D₃-a, D₄-a | |
| B8 | 20 × 20 × 512 | D₁-b, D₂-b, | M × M × N_{c} |
| | | D₃-b, D₄-b | |
| B9 | 20 × 20 × 512 | D5 | 34000 × 4 |
| B10 | 20 × 20 × 512 | D6 | 34000 × N_{c} |

Example 3—Details of the Feature Maps from Backbone Module

The following example provides details of the feature maps for the at least four outputs of the embodiment of the backbone module from FIG. 4. FIG. 11 illustrates feature maps @id=64 of the outputs of the Backbone for B3 (top left), B5 (top right), B7 (bottom left) and B10 (bottom right). Four feature maps (superimposed on the floorplan image) are represented as heat maps which are generated by encoding the grayscale feature maps using pseudo colors. The underlying grayscale feature maps are obtained by selecting the channel at index 64 and then normalizing its pixel values between 0 and 255.

Observing these heat maps, it can be seen that in the B3 heat map, several smaller-sized objects within the floor plan image are prominently highlighted, including digits (numbers), letters, and fine lines. As the feature maps progress to B5, B7, and B10, they gradually show larger highlighted regions. This progression demonstrates the backbone module's ability to effectively capture objects at different scales, with coarser feature maps (e.g., B10) representing larger, more abstract features, and finer feature maps (e.g., B3) preserving details of smaller elements. This multi-scale feature representation is crucial for comprehensive object detection and semantic understanding across the varying sizes of architectural elements in floor plan images.

Example 4—Details of Feature Map Sizes within the Object Detector

The following example provides details of the feature maps sizes within the C2f, Bottleneck, and SPPF modules of the network architecture. Specifically, for the four C2f modules arranged from upstream to downstream within the backbone module, the C1 parameter (representing output channels for a certain convolutional layer within the C2f module) is configured sequentially as 128, 256, 512, and 512. The C2 parameter (representing output channels for another convolutional layer within the C2f module) maintains the same values as C1 within the backbone module. Table 3 also shows the sizes of the feature maps in the C2f, and AC-CBAM.

TABLE 3
Sizes of feature maps

| Feature | Size | Feature | Size |
|---|---|---|---|
| CF1 | M × M × C₁ | SP1, SP2, SP3, | M × M × 512 |
| | | SP4, SP5, SP7 | |
| CF2, CF7 | M × M × C₂ | SP6 | M × M × 2048 |
| CF3, CF4, CF5 | M × M × 0.5C₂ | A1 | M × M × C₁ |
| CF6 | M × M × 0.5(n + | A2, A3, A4, CA1, | M × M × C₂ |
| | 2)C₁ | CA2, CA3 | |
| BT1, BT2, | M × M × 0.5C₂ | | |
| BT3, BT4 | | | |

The specific parameters (C1, C2) for the C2f module across different stages of the network were chosen and optimized to achieve the improved performance. In Stage 1, the (C1, C2) configuration is set to (1024, 512). For Stage 2, the configuration is (768, 256). In Stage 3, the two C2fs within the AC-CBAM are set to (384, 128) and (128, 128), respectively. Moving to Stage 4, the two C2fs within the AC-CBAM utilize (384, 256) and (256, 256). In Stage 5, their configurations are (768, 512) and (512, 512). Finally, for Stage 6, the two C2fs in the AC-CBAM are configured with (1024, 512) and (512, 512).

### Example 5—Detection Convolution Blocks and Output Feature Maps

The following example provides an embodiment of the structure for the at least two parallel branches that predict the localization (top branch) and classification (bottom branch) as part of a DCB are provided. At least three convolutions are performed in each branch of the DCB. The top branch has an output, with size M×M×64, which is used to predict the sizes and locations of bounding boxes. The 64-dimension vector Dk-a describes the distribution focal loss (DFL) of the prediction for the bounding boxes.

FIG. 9A shows one example feature map from the D1-a output (with size: 160×160×64) of the DCB along Path1. The feature map (superimposed on the floorplan image) is represented as a heat map which is generated by encoding the grayscale feature map using pseudo colors. The grayscale feature map is obtained by picking a channel at the 2nd index from D1-a and then normalized between 0 and 255. It is observed that the feature map shows several highlighted (in red) rectangular regions at the positions of the target objects (e.g., doors, and sinks), which indicates that the D1-a tends to predict bounding boxes around the target objects. The top branch has an output, with size M×M×64, which is used to predict the sizes and locations of bounding boxes. The 64-dimension vector Dk-a describes the distribution focal loss (DFL) of the prediction for the bounding boxes. The outputs Dk-a from each path are fed into the BBP block, and the outputs Dk-b from each path are fed into the CP block. The output of the bottom branch in a DCB has a size of M×M×N_{c} that is used to predict the classification.

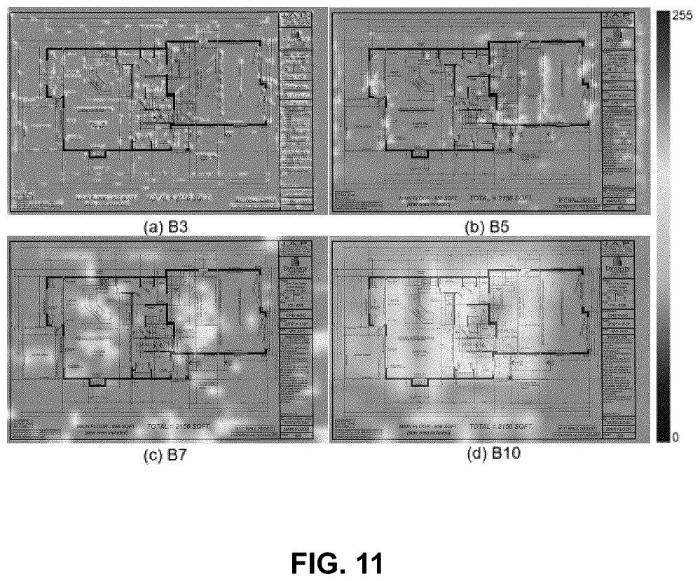

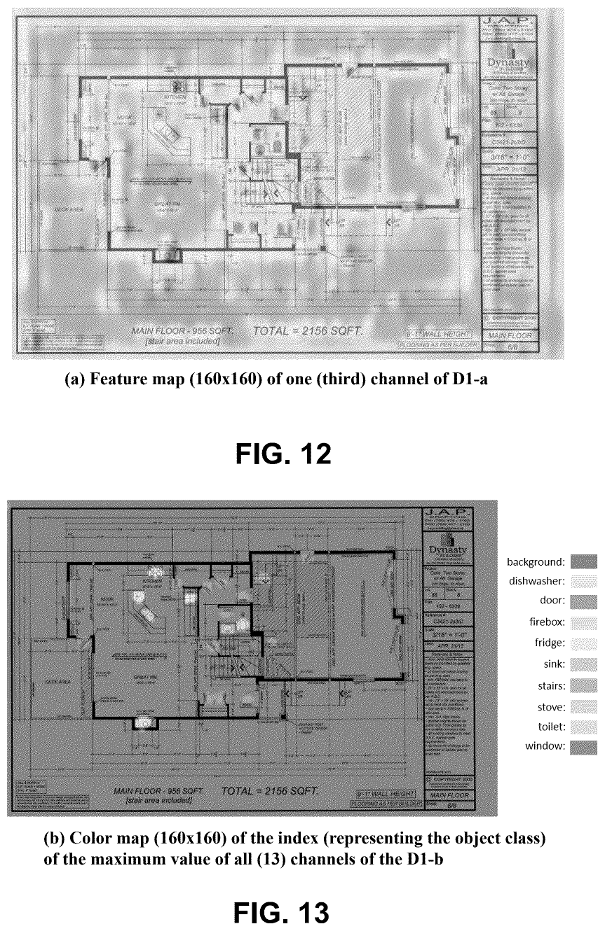

FIG. 12 shows one example feature map from the D1-b output (with a size of 160×160×the number of channels) of the DCB along Path1. FIG. 13 is represented in the same way as FIG. 12, but the value (or color map) is obtained by selecting the index of the maximum across all channels. It is observed that FIG. 13 shows several highlighted regions with distinct colors at the positions of the target objects (e.g., doors, and sinks), which indicates that the D1-b predictions tend to classify the object to the category with highest score. Note that in this floor plan image example, four object types (bathtub, shower, washer, dryer) do not appear and as a result only nine object types are shown in the label.

### Example 6—Detection Convolution Blocks and Output Feature Maps

The following example provides specific embodiments of the structure of the Detection Convolution Blocks (DCBs). Similar to the BBP (Bounding Box Postprocessing) module, the bottom outputs (specifically, D1-b, D2-b, D3-b, and D4-b) from the four DCBs are processed using the Classification Postprocessing (CP) block. The schematic of this CP block is detailed in FIG. 8C. The sizes of the internal feature maps within the CP block are itemized in Table 3. The final output of the CP block, designated as CP5, includes object class predictions at four distinct scales, allowing for comprehensive classification of objects regardless of their size in the input image.

The feature maps BBP6 and CP5 represent the detected bounding boxes and the object classes. The final step in the Detection module is to select the most appropriate bounding boxes and classification results from the BBP and CP outputs using a non-maximum suppression (NMS) as shown in Algorithm 1. The NMS algorithm produces at least two outputs of size N×4 and N×1 where N is the number of detected objects. The first output shows the location and size of a bounding box, and the second output shows the corresponding object class. During the process of merging multiple detections that refer to the same physical object into a single, definitive detection, a configurable Intersection over Union (IoU) threshold, λₜₕᵣₑₛ, is applied. In this embodiment, a λₜₕᵣₑₛ value of 0.5 is utilized for comparing the similarity between two bounding boxes.

### Example 7—Performance Evaluation and Validation

The following example provides an example implementation of the object detector (i.e., the AchNetv2 architecture) as described above, as well as an exemplary process for evaluating the training and performance of the object detector (ArchNetv2).

In an example implementation of the system of the present disclosure, the system was configured as a Python-3.10.11, torch-1.11.0, Tesla T4, 15102MiB. FIG. 2 shows an example object category list considered in an exemplary embodiment of the present disclosure. As shown in FIG. 4, there are three modules in the ArchNetv2. Each of these three modules include CNNs that require training. The final performance evaluation is carried out using the testing dataset consisting of eighty images. According to the experimental attempts and hardware facilities, the batch size is four and epoch is five hundred. The training process is evaluated by use of the validation dataset consisting of sixty-four images. Early stopping will be executed if the network training is not improved after one-hundred epochs by tracking the network performance on the validation dataset.

The evaluation metrics of precision (P), recall (R), average precision (AP) and mean average precision (m_{AP}) are used herein. For a given object class, the P and R are calculated as follows:

$$P = \frac{T P}{T P + F P}$$

$$R = \frac{T P}{T P + F N}$$

where TP is the number of correctly predicted bounding boxes, FP is the number of incorrectly predicted bounding box, and FN is the number of unpredicted objects. The AP for an object class is calculated by the area under the precision/recall (PR) curve for the detections. Note that the PR curve is a plot of precision and recall at varying confidence values.

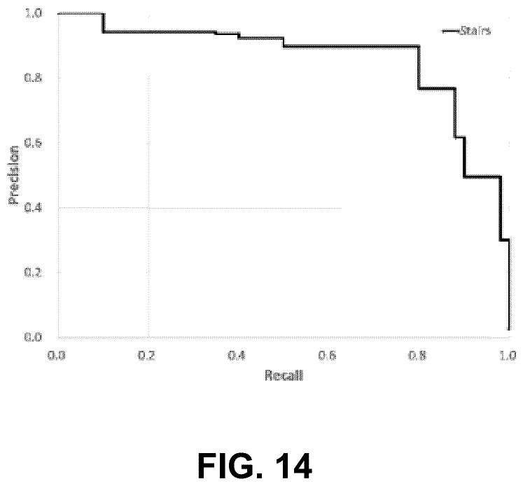

Different confidence values lead to various values of TP, FP, FN. The IoU threshold is 0.5 in the calculation of P and R. The AP is calculated as follows:

$$AP = {\sum }_{k = 1}^{{N}_{R} - 1} ( {R}_{k + 1} - {R}_{k} ) \times {P}_{k} ( {R}_{k} )$$

where NR is the number of recalls. An example of a PR curve is shown in FIG. 14. The mAP for all object classes is calculated as follows:

$$mAP = \frac{1}{{N}_{c}} {\sum }_{i = 1}^{{N}_{c}} {AP}_{i}$$

where N_{c} is the number of classes. Table 4 presents the performance comparison between the proposed ArchNetv2 and a few state-of-the-art techniques on the testing dataset.

TABLE 4
Performance comparison with existing technique.

| AP_{0.5} % | TOD | YOLOv3 | ArchNet | YOLOv7 | YOLOv8n | YOLOv8l | ArchNetv2 |
|---|---|---|---|---|---|---|---|
| Door | 82.19 | 89.98 | 90.48 | 96.20 | 90.60 | 96.30 | 98.10 |
| Stairs | 80.87 | 53.68 | 67.54 | 99.00 | 91.90 | 99.40 | 95.30 |
| Sink | 77.27 | 90.40 | 88.27 | 97.60 | 87.60 | 93.70 | 98.50 |
| Toilet | 80.41 | 90.09 | 92.75 | 98.60 | 85.30 | 93.70 | 99.50 |
| Firebox | 86.24 | 83.28 | 89.31 | 99.00 | 93.70 | 98.90 | 99.50 |
| Fridge | 52.58 | 43.66 | 49.67 | 52.60 | 64.10 | 78.10 | 67.90 |
| Stove | 95.79 | 66.67 | 66.67 | 99.00 | 85.40 | 99.50 | 99.50 |
| Dishes | 63.23 | 57.63 | 62.02 | 58.80 | 66.50 | 64.80 | 95.70 |
| Bathtub | 80.78 | 93.06 | 91.89 | 99.70 | 97.70 | 99.50 | 99.20 |
| Shower | 55.03 | 38.57 | 42.28 | 58.00 | 69.50 | 80.50 | 77.50 |
| Dryer | 49.78 | 72.50 | 64.45 | 43.20 | 65.50 | 80.20 | 98.70 |
| Washer | 65.62 | 80.00 | 81.52 | 77.40 | 73.00 | 86.90 | 98.70 |
| Window | 68.28 | 84.64 | 84.44 | 90.20 | 68.10 | 70.00 | 87.40 |
| mAP_{0.5} | 72.16 | 72.62 | 74.71 | 82.40 | 79.90 | 87.80 | 93.50 |

Table 4 presents the performance comparison between the proposed ArchNetv2 and a few state-of-the-art techniques on the testing dataset. These results have been obtained with an IoU threshold, λₜₕᵣₑₛ=0.5. Note that the YOLOv8 network has a few variations (i.e., YOLOv8n, YOLOv8s, YOLOv8m, YOLOv8l, YOLOv8x) with different numbers of parameters and speeds. For example, YOLOv8n has the least number of parameters and the fastest speed but YOLOv8x is the heaviest and the slowest. The YOLOv8l and YOLOv8x have been observed to provide similar detection accuracy (e.g., 87.80% and 87.90%) on the architectural floor plans. Therefore, the performance of YOLOv8x is not included in Table 4

In the example experiments provided herein, the mAP is improved by 21.34% relative to TOD, by 20.88% relative to YOLOv3, by 18.79% relative to ArchNet, by 11.10% relative to YOLOv7, by 13.6% relative to YOLOv8n, by 5.70% relative to YOLOv8l. Table 5 shows an ablation study of the ArchNetv2 utilizing the YOLOv8 model.

TABLE 5
Ablation study of the ArchNetv2 utilizing the YOLOv8 model.

| | mAP_{0.5} | mAP_{0.95} | Parameters | Speeds |
|---|---|---|---|---|
| Method | (%) | (%) | (M) | (ms/image) |
| YOLOv8l | 87.80 | 63.80 | 82.30 | 54.70 |
| ArchNetv2-a: | 91.80 | 68.70 | 83.60 | 55.50 |
| YOLOv8l + | | | | |
| Stages 3,4 + | | | | |
| Path1 | | | | |
| ArchNetv2-b: | 88.90 | 64.50 | 85.80 | 57.60 |
| YOLOv8l + | | | | |
| AC-CBAM | | | | |
| ArchNetv2: | 93.50 | 69.00 | 90.60 | 62.50 |
| YOLOv8l + | | | | |
| Stages 3,4 + | | | | |
| Path1 + AC-CBAM | | | | |

If the input paths for the Detection increase from 3 (i.e., the YOLOv8l in Table 5) to 4 (i.e., ArchNetv2-a in Table 5), the mAP_{0.5} and mAP_{0.95} are enhanced by 4.00% and 4.90%, respectively, with little impact on the model size and inference speed. Note that in this example case, the stages in the MLP module uses C2f instead of AC-CBAM. In addition, the mAP_{0.5} and mAP_{0.95} of the ArchNetv2-b where AC-CBAM is used with retaining the three input paths for the Detection like the YOLOv8 are 1.10% and 0.70% higher than the YOLOv8 method. The proposed ArchNetv2 has the highest accuracy with a mAP_{0.5} at 93.50% and a mAP_{0.95} at 69.00% owing to the collective contributions of the additional input path in Detection and the AC-CBAM in MLP.

Tables 4 and 5 show that the proposed ArchNetv2 has a superior performance over the YOLOv8 on the architectural floor plans. The following is an explanation as to how the object detection is improved in the ArchNetv2 compared to the YOLOv8.

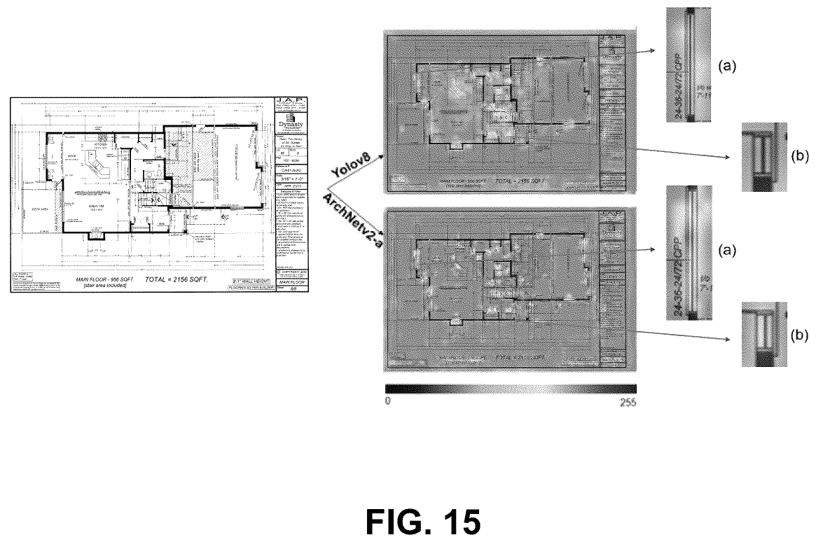

FIG. 4 shows that the ArchNetv2 introduces at least one new detection head (i. e., N3) compared to the YOLOv8 that has only three detection heads (i. e., N4, N5, N6). The N3 feature maps, having higher resolution (compared to N4-N6), are able to capture the small objects better. FIG. 15 shows the comparison of a shallow feature map outputted from the MLP between the YOLOv8 and the ArchNetv2-a. ArchNetv2-a is a sub-model of ArchNetv2 by incorporating the new detection head only (the AC-CBAM is excluded), as described in Table 5. The shallow feature map refers to the largest feature map outputted from the MLP. In each feature map, two windows are cropped as the examples: one window is long and narrow (denoted as (a) in FIG. 15), and the other is short and narrow (denoted as (b) in FIG. 15). Both the YOLOv8 and the ArchNetv2-a can capture the window (a), but the ArchNetv2-a shows a stronger focus on the window (a) and has a higher possibility to detect it than the YOLOv8. The window (b) is not captured in the feature map by the YOLOv8. However, the ArchNetv2-a tends to highlight the window (b) to an extent.

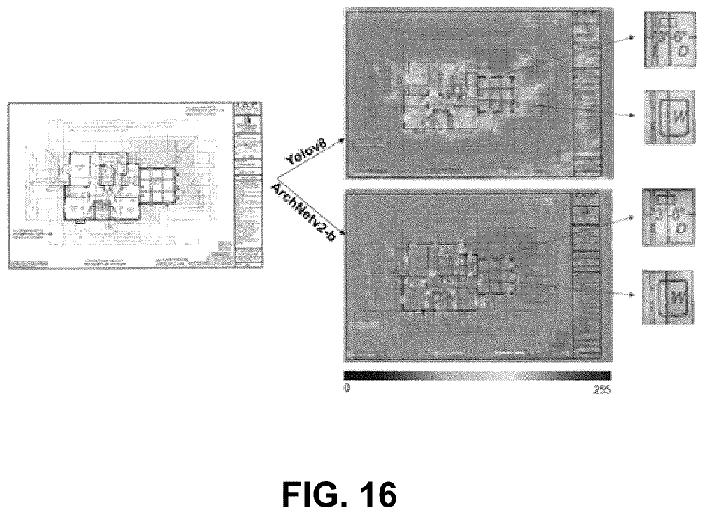

The new AC-CBAM module in the MLP of the ArchNetv2 helps pay attention to the important information of the objects, such as letters. FIG. 16 shows another floor plan detection example on the comparison of the shallow feature map outputted from the MLP between the YOLOv8 and the proposed ArchNetv2-b. ArchNetv2-b is another sub-model of ArchNetv2 by incorporating the AC-CBAM only (Stages 3,4 and Path 1 are excluded). In this example, the objects dryer and washer are cropped from the feature maps. The dryer is typically marked by a “D” inside of its boundary, and the washer by “W”. The feature maps show that both the YOLOv8 and the ArchNetv2-b can capture the dryer and the washer. However, the highlighted regions by YOLOv8 show the weaker heat and the center of the highlighted regions are shifted away from the target objects. The feature map of the ArchNetv2 shows a stronger heat on the dryer and the washer regions. The centers of the heat regions are also consistent with those of the target objects.

FIG. 17 shows an example of the visualization of object detection results predicted by the proposed ArchNetv2. The ArchNetv2 works well on the prediction on the big-size objects (e.g., the stairs in the middle of the floor plan) and the small-size objects (e.g., the windows and dishwashers). The ArchNetv2 can also detect the stairs in the garage when lots of slash lines overlap with the stairs.

### Example 8—Training of CNNs within Modules

The following example provides an exemplary process for training the modules within the CNNs of the backbone, mid-level processing (MLP), detection, text analysis, and segmentation modules. During the training processes, the weights of these CNNs are iteratively updated to minimize the overall loss function of the entire network, thereby optimizing its performance. The proposed network is designed to perform two primary tasks: room boundary prediction and room type prediction. To ensure a balanced contribution from both tasks during training, a weighted loss function is employed, defined as:

$$Loss = {w}_{b} {L}_{b} + {w}_{r} {L}_{r}$$

where Lb is the loss function for boundary prediction and Lᵣ is the loss function for room type prediction. The weights are calculated as follows:

$${w}_{b} = \frac{{N}_{r}}{{N}_{b} + {N}_{r}} and {w}_{r} = \frac{{N}_{b}}{{N}_{b} + {N}_{r}}$$

where Nb and Nᵣ are the numbers of boundary pixels and room pixels, respectively. In Eq. (6), the loss function for a specific task (i.e., Lb or Lᵣ) is defined by:

$${L}_{task} = - \frac{N - {N}_{i}}{{\sum }_{j = 1}^{{N}_{c}} ( N - {N}_{j} )} {\sum }_{i = 1}^{{N}_{c}} ( {y}_{i} log ( {p}_{i} ) )$$

where N is the total number of ground-truth pixels, N_{c} is the number of classes for the task, yi is the label for class i, and pi is the predicted probability of class i.

The proposed network is trained on Google Colab GPU High-RAM environment, though it can be adapted for various other suitable computational systems. In this example, the Adam optimizer is utilized for the training process over 210 epochs. Table 8 details the dataset setup for both the R3D and the augmented CAFP datasets across the training, validation, and testing stages. As indicated in Table 8, each floor plan in the R3D dataset is segmented into 9 distinct categories. Given that CAFP floor plans typically contain more detailed information than R3D floor plans, the CAFP floor plans are segmented into 11 categories. A batch size of 1 is used during training.

In the present disclosure, Intersection over Union (IoU) is used as the metric to evaluate the semantic segmentation performance. The IoU of class i is defined as follows:

$${IoU}_{i} = \frac{{S}_{I}}{{S}_{U}}$$

where SI is the intersection area of the predicted segmentation and the groundtruth for class i, SU is the union area of the predicted segmentation and the groundtruth for class i. As the semantic segmentation involves more than two classes, the mIoU, as defined below, is used as the overall performance metric.

$$mIoU = \frac{{\sum }_{i} {IoU}_{i}}{{N}_{c}}$$

### Example 9—Inputs to the Concact Module of the MRBAM

The following example provides an embodiment of the inputs to the Concact module within the MRBAM. In this example, the plurality of inputs to the Contact module includes five inputs. The five inputs to the Concat module produce the output T_{c}(N, W, H, 5C) where N is the number, W is the width, H is the height, and C is the number of channels. The details of each of these five inputs are presented below. In this specific example:

The first input to the Concat module is w₁T_{b}(N, W, H, C).

The second input to the Concat module is w₂T_{b2} where

$${T}_{b 2} = C o n v Unit \{ {T}_{b} ( N , W , H , C ) ⊗ {T}_{r} ( N , W , H , C ) \} .$$

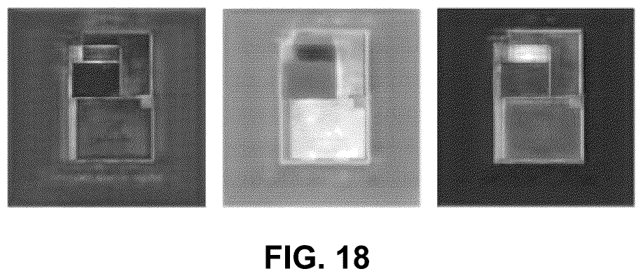

Note that ⊗ is the elementwise multiplication operator. Here the value of n is 2. An example of the T_{b2} visualization is shown in FIG. 18 where greyscale feature maps are obtained by averaging the feature maps across the depth and then normalized between 0 and 255.

The third input to the Concat module is w₃Tₚ₁ where

$${T}_{p 1} = UpConv 2 d \{ {T}_{p} ( N , W / 2 , H / 2 , C ) \}$$

The fourth input to the Concat module is w₄Tᵣ₅ where

$${T}_{r 5} = C o n v 2 d \{ {T}_{r 3} ⊗ {T}_{b 2} \} .$$

$${T}_{r 3} = B R B C o n v \{ {T}_{r 1} ⊗ {T}_{b 2} \}$$

$${T}_{r 1} = C o n v U n i t \{ {T}_{r} ( N , W , H , C ) \}$$

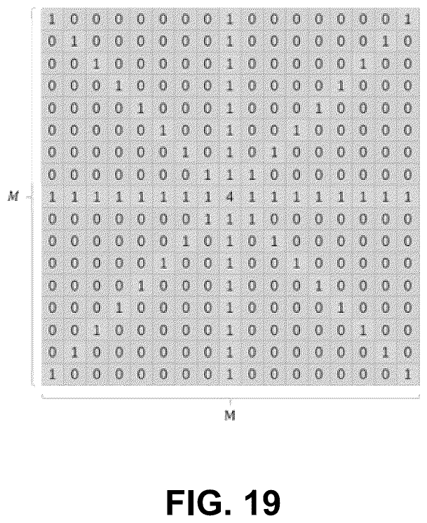

Note that the BRBConv(.) is a boundary-refinement-block convolutional layer to refine the room boundary features. The kernels are square matrices of size M*M where M is an odd integer. The size of the kernel in the BRBConv is one quarter of the input feature size. A kernel example with M=17 is shown in FIG. 19. Note that the matrix elements are ones in the horizontal, vertical and diagonal directions, and the center element is four.

The fifth input to the Concat module is w₅Tᵣ(N,W,H,C).

Five different inputs are concatenated by a MRBAM unit. In this example, the input weights [w1, w2, w3, w4, w5]=[1, 1, 1, 7, 1] were used to obtain the best performance. The output T_{c} (N, W, H, 5C) of the concatenation layer is passed through a convolutional layer to reduce the depth from 5C to 2C. An example of the Tₒᵤₜ visualization is shown in FIG. 5c.

### Example 10—FC Module and Feature Map Sizes

The following example provides an embodiment of the FC module within the segmentation module. As noted above, a function of FC module is to predict the final floor plan semantic segmentation result based on the feature maps from the RBD and MRBAM modules. In this example FC module, the inputs B1 and M1 pass through the U modules, resulting in outputs C1 and C2, respectively. As depicted in Table 7, the size of C1 is the same as that of the original input image and the depth of C1 is 3 indicating the prediction result of background, wall, or door/window. Similarly, C2 has the same size as that of the original input image and the depth of C2 is (Nc-2) indicating the prediction result of all segmentation class excluding the wall, and door/window.

TABLE 7
The size of various feature maps B1-B4, R1-R4,
M1-M4 and C1-C3 in FIG. 2. Note that N_{c} denotes
the total number of segmentation classes:

| B1/R1/M1 | B2/R2/M2 | B3/R3/M3 | B4/R4/M4 |
|---|---|---|---|
| 256 × 256 × 32 | 128 × 128 × 64 | 64 × 64 × 128 | 32 × 32 × 256 |

| C1 | C2 | C3 |
|---|---|---|
| 512 × 512 × 3 | 512 × 512 × (N_{c}-2) | 512 × 512 × N_{c} |

### Example 11—Performance Analysis

The following example shows the performance of three examples of the proposed FloorNet using VGG16, ResNet34 and DenseNet121, respectively, as the encoder modules. It is observed that for the R3D dataset, the mIoU of the DenseNet121-based network is 69%, which is 10% higher than that of the VGG16 network. For the CAFP dataset, the mIoU of the DenseNet121 network is 60%, which is 9% higher than that of the VGG16 network.

TABLE 9
Performance of the proposed FloorNet (in FIG. 8) with VGG16,
ResNet34 and DenseNet121 models in the CNN encoder module:

| | |
|---|---|
| Encoder | mIoU (%) |

| Model | R3D | CAFP |
|---|---|---|
| VGG16 | 59.08 | 51.31 |
| ResNet 34 | 66.87 | 55.34 |
| DenseNet 121 | 68.65 | 59.88 |

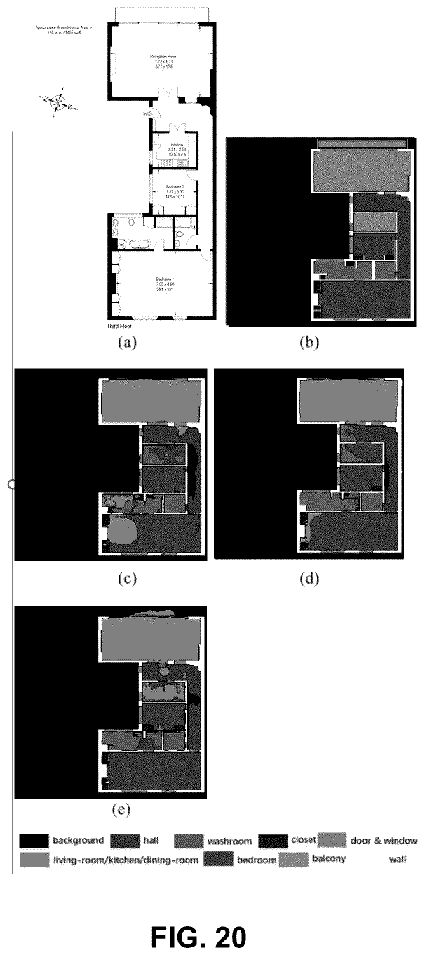

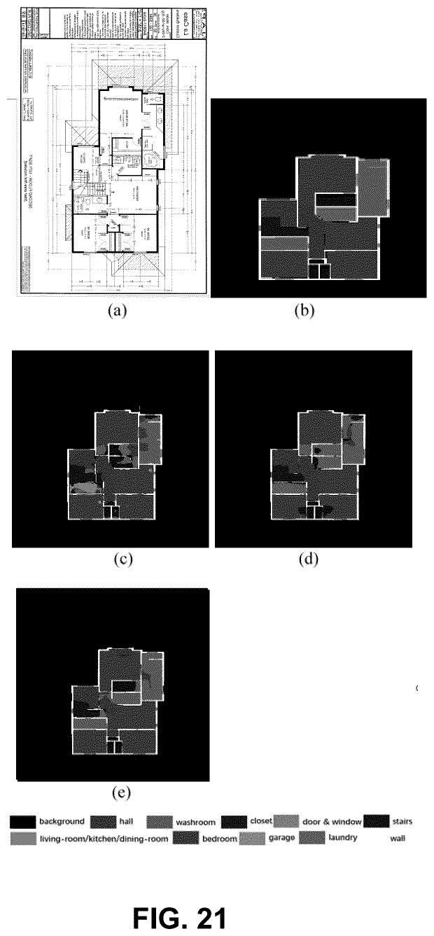

FIGS. 20 and 21 show the visual comparison of floor plan recognition results produced by our method based on the R3D and CAFP datasets, respectively. From the figures, the prediction of the DenseNet121-based network has a better performance than the VGG16-based and the ResNet34-based networks because the prediction of the DenseNet121 has less noise in large spaces. FIGS. 20 and 21 specifically provides a visual comparison of floor plan segmentation results produced by the proposed method for an image from the R3D dataset: a) original image, b) ground truth, c) prediction of the VGG16-based network, d) prediction of the ResNet34-based network, e) prediction of the DenseNet121-based network.

### Example 12—Performance Analysis and Comparison to Prior Art RBGA-CNN

The following example provides a performance comparison between a prior art RBGA-CNN, DED and the proposed DenseNet121-based FloorNet model for the R3D and CAFP datasets. As shown below in Table 10, for the R3D dataset, the mIoU of the proposed network is 24%, and 15% higher than that of the DED, and the RBGA-CNN, respectively.

TABLE 10
Performance comparison of the proposed technique
with the state-of-the-art techniques DED, and RBGA-
CNN. The last row shows the performance of the proposed
technique using the DenseNet121 encoder:

mIoU (%)

| Methods | R3D | CAFP |
|---|---|---|
| DED | 44.73 | 40.07 |
| RBGA-CNN | 54.22 | 49.02 |
| Proposed | 68.65 | 59.88 |

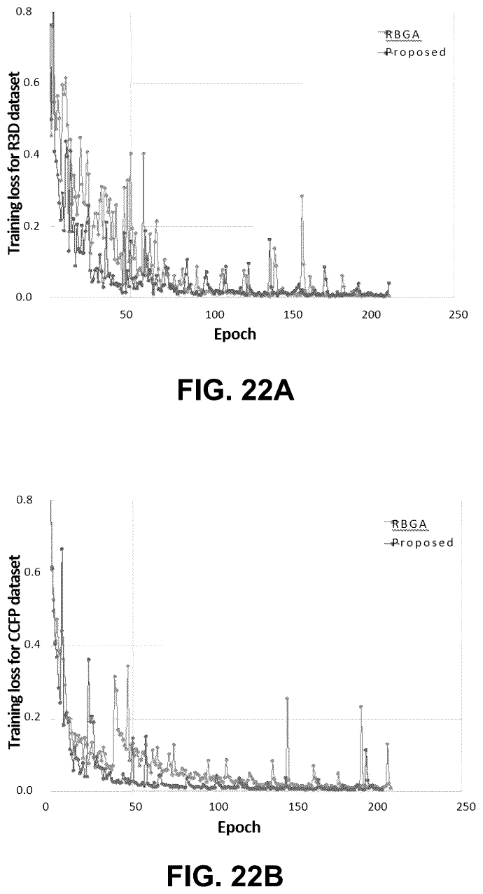

When the CAFP dataset is used, the proposed technique also shows better performance than the DED and RBGA-CNN methods. Note that because of the attention mechanism, the RBGA-CNN, and the proposed work provides a significant performance improvement over the DED model. FIGS. 22A and 22B show the training loss for the prior art RBGA-CNN, and FloorNet model. Although both techniques use the attention mechanism, the proposed technique can achieve a lower loss in the training process. Note that all experimental evaluations were performed on Google Colab GPU High-RAM environment. The inference time required for the FloorNet model is approximately 65-75 ms for one image, which shows relatively low computational requirement for testing environment.

### Example 13—Ablation Study Analysis

The following example provides a detailed ablation study to show the improvements caused by the above-described FloorNet architecture. The proposed FloorNet includes all modifications on the CNN Encoder, RBD, RTD and the attention module. The results show that the mIoU of the network is enhanced when the new encoder, the improved decoders and attention module are introduced. Table 11 shows the experimental results of the ablation study. The ablation study results (in Table 11) show that the attention module is beneficial for the floor plan segmentation compared to the prior art RBGA-CNN in Example 12. This table presents a qualitative analysis of the reasons.

TABLE 11
Ablation study on the improvements offered by the enhancements
proposed in various modules based on the CAFP dataset.

| Architecture | | mIoU (%) |
|---|---|---|
| RBGA-CNN: | CNN Encoder | 49.02 |
| | (VGG) + RBD^{v1} + RTD^{v1} + RBGA | |
| FloorNet-a: | CNN Encoder | 50.83 |
| | (ResNet) + RBD^{v1} + RTD^{v1} + RBGA | |
| FloorNet-b: | CNN Encoder | 54.21 |
| (i.e., BAAM- | (ResNet) + RBD^{v1} + RTD^{v1} + BAAM | |
| CNN): | | |
| FloorNet-c: | CNN Encoder | 54.95 |
| | (DenseNet) + RBD^{v1} + RTD^{v1} + BAAM | |
| FloorNet-d: | CNN Encoder | 56.45 |
| | (DenseNet) + RBD^{v2} + RTD^{v2} + BAAM | |
| FloorNet: | CNN Encoder | 59.88 |
| | (DenseNet) + RBD^{v2} + RTD^{v2} + MRBAM | |

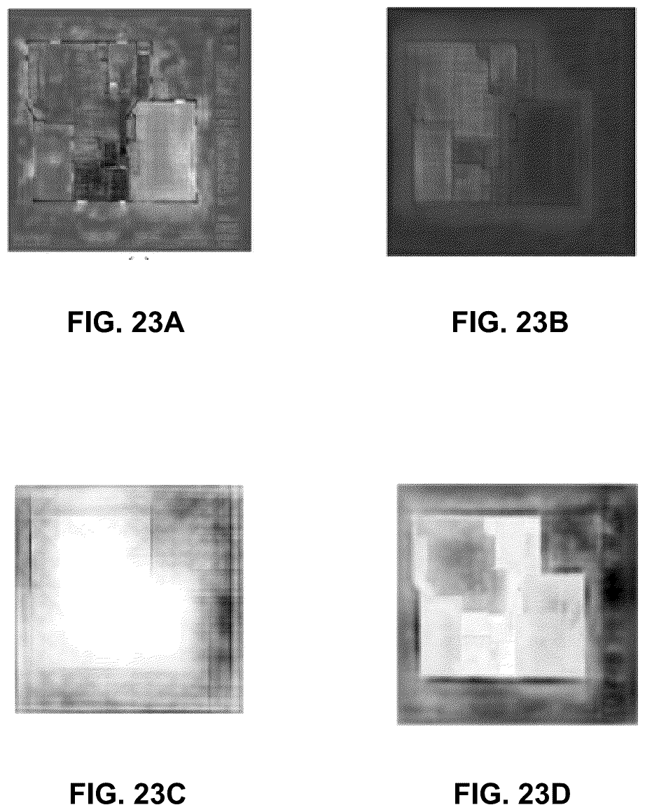

FIGS. 23A to 23D show examples (from CAFP dataset) of gray-scale visualization for the feature transformation in the fourth MRBAM unit (MRBAM consists of four MRBAM units (shown in FIG. 8). The grayscale feature maps are obtained by averaging the feature maps across the depth and then normalized between 0 and 255. FIG. 23A shows the well-learned room boundary (RB) feature map that is an input for this MRBAM unit. FIG. 23B also shows the room type (RT) feature map that is another input for this MRBAM unit. In each room (e.g., the red box), the pixels in the center area different from the pixels near the boundaries, indicating an inconsistent prediction of the room type. The MRBAM fuses the feature maps (e.g., FIGS. 12 and 13) from two tasks (i.e., RB prediction and RT prediction) through elementwise multiplication. The directional kernels are used to process the fused features to address the problems that the room boundaries in a floor plan are not only horizontal or vertical (see FIG. 23C). As shown in FIG. 23D, the well-predicted room boundary is helpful to suppress the noises for the room type pixels near the room boundaries, resulting in a uniform and improved room type feature map.

All publications, patents and patent applications cited above are herein incorporated by reference in their entirety to the same extent as if each individual publication, patent, or patent application was specifically and individually indicated to be incorporated by reference in its entirety.

Although certain embodiments have been described herein in detail, it will be understood by those skilled in the art that variations may be made thereto without departing from the spirit of the invention or the scope of the appended claims.

What is claimed is:

1. A system for processing an input architectural floor plan image, the system comprising a computer processor and a non-transitory computer-readable medium comprising one or more sequences of instructions for detecting objects in a floor plan using a neural network, the system comprising:
an object detector comprising a first set of sequences executed by the computer processor to at least detect and classify a plurality of objects in an architectural floor plan image to output object data;
a text analyzer comprising a second set of sequences executed by the computer processor to at least identify and extract text from the architectural floor plan image to output machine-readable text data;
a segmentation module comprising a third set of sequences executed by the computer processor to at least divide the architectural floor plan image into at least one region; and
a semantic labeler comprising a fourth set of sequences executed by the computer processor to at least determine a semantic label for each region of the at least one region based, at least in part, on the object data and the text data from the architectural floor plan image;
wherein the system quantifies building parameters of the at least one region based on the semantic label of the at least one region for generating a structured, machine-interpretable representation of the architectural floorplan.

2. The system of claim 1, wherein the object data includes object classes and object locations for the plurality of objects within the architectural floor plan image, and wherein the machine-readable text data includes textual content and textual content locations within the architectural floor plan image.

3. The system of claim 1, wherein the building parameters of the at least one region form a structured, machine-interpretable digital model of the architectural floorplan; and
wherein the model is structured to enhance the computer processor functional capabilities for automated architectural analysis by transforming unstructured data in the architectural floorplan image into structured machine-interpretable design data for downstream processes.

4. The system of claim 3, wherein the system is configurable to utilize the determined building parameters for at least one of: generating a building information model (BIM), estimating construction costs, and verifying building code compliance.

5. The system of claim 1, wherein the object detector is configurable to apply a neural network for outputting the object data of the plurality of objects.

6. The system of claim 5, wherein the neural network comprises:
a backbone module configurable to analyze the architectural floor plan image to generate a set of floorplan feature maps;
a mid-level processing (MLP) module configurable to learn from and tune the set of floorplan feature maps for generating an enhanced set of floorplan feature maps; and
a detection module configurable to classify the plurality of objects based on the enhanced set of floorplan feature maps from the MLP module.

7. The system of claim 6, wherein the detection module comprises a plurality of detection heads configurable to operate independently for localizing and classifying the plurality of objects;
wherein at least one of the plurality of detection heads is specifically adapted to detect small-sized objects, thereby expanding inputs of contextual information, increasing a number of candidate proposals, and improving detection performance on small-size objects within the architectural floor plan image.

8. The system of claim 7, wherein the detection module is further configurable to utilize rectangular bounding boxes for identifying and classifying the object data for the plurality of objects by predicting a location and size of the rectangular bounding boxes during classification of the plurality of objects.

9. The system of claim 6, wherein the detection module is further structured for executing an object detection process that includes:
receiving the enhanced set of floorplan feature maps from the MLP module; and
processing the enhanced set of floorplan feature maps through a plurality of detection convolution blocks for determining the bounding boxes and classifications for the plurality of objects within the architectural floor plan image.

10. The system of claim 9, wherein the detection module is configurable to process the enhanced set of floorplan feature maps on at least four parallel processing paths that correspond to at least four feature maps generated by the backbone module.

11. The system of claim 6, wherein the MLP module includes at least one attention mechanism for tuning the floorplan feature maps to generate the enhanced set of floorplan feature maps, the at least one attention mechanism having a plurality of processing stages that each generate a unique feature map of the enhanced floorplan features.

12. The system of claim 11, wherein the at least one attention mechanism includes an Attention-gated Convolutional Block Attention Module (AC-CBAM) that is configurable to direct the object detector to advantageous features that are beneficial for object detection.

13. The system of claim 12, wherein the AC-CBAM comprises a CBAM attention mechanism that is integrated with first and second C2f modules;
wherein the CBAM attention mechanism suppress invalid features learned from the first C2f module;
wherein the second C2f module retunes the advantageous features.

14. The system of claim 1, wherein the segmentation module comprises:
a semantic segmentation component configurable to classify each pixel of a plurality of pixels that form the architectural floor plan image into one of a plurality of classes of region boundaries or one of a plurality of classes of region areas; and
an image segmentation component configurable to divide the architectural floor plan image into at least one region based on the plurality of classes of region boundaries and the plurality of classes of region areas for the plurality of pixels in the architectural floor plan image.

15. The system of claim 14, further comprising a label determination module that is configurable to determine the semantic label for each region of the at least one region by:
determining if at least a subset of the text data from the architectural floor plan image is associated with the region;
wherein when the subset of the text data is associated with the region, the label of the region is generated based on the subset of the text data; and
wherein when the subset of the text data is not associated with the region, the label of the region is at least one of i) a label that is inferred from the plurality of detected and classified objects, and ii) a label that is determined by the label of a maximum classified region-area pixels.

16. A computer-implemented method for processing an input architectural floor plan image to determine building parameters for the architectural floor plan, the method comprising:
performing at least one object detection step on the architectural floor plan image for detecting and classifying a plurality of objects in the architectural floor plan image to output object data, the object data including object classes and object locations for the plurality of objects within the architectural floor plan image;
performing at least one text analysis step for identifying and extracting text from the architectural floor plan image to output text data, the text data including textual content and textual content locations within the architectural floor plan image;
performing at least one segmentation step for dividing the architectural floor plan image into at least one region;
determining a semantic label for each region of the at least one region based, at least in part, on the object data and the text data; and
quantifying the building parameters of the at least one region based on the semantic label of the at least one region.

17. The method of claim 16, wherein the at least one object detection step for outputting the object data of the plurality of objects includes applying a neural network, the neural network comprises:
a backbone module for analyzing the architectural floor plan image to generate a set of floorplan feature maps;
a mid-level processing (MLP) module for learning from and tuning the set of floorplan feature maps for generating an enhanced set of floorplan feature maps; and
a detection module for classifying the plurality of objects based on the enhanced set of floorplan feature maps from the MLP module.

18. The method of claim 16, wherein the at least one segmentation step comprises:
a semantic segmentation step for classifying each pixel of the plurality of pixels that form the architectural floor plan image into one of a plurality of classes of region boundaries or one of a plurality of classes of region areas; and
an image segmentation step for dividing the architectural floor plan image into at least one region based on the plurality of classes of region boundaries and the plurality of classes of region areas for the plurality of pixels in the architectural floor plan image.

19. The method of claim 16, wherein determining the semantic label for each region of the at least one region comprises:
determining if at least a subset of the text data is associated with the region;
wherein when the subset of the text data is associated with the region, the label of the region is generated based on the subset of the text data; and
wherein when the subset of the text data is not associated with the region, the label of the region is at least one of i) a label that is inferred from the plurality of detected and classified objects, and ii) a label that is determined by the label of a maximum classified region-area pixels.

20. A computer-implemented, deep-learning method for processing an input architectural floor plan image, the method comprising:
executing a trained deep learning model to process the architectural floor plan image;
performing, via the deep learning model, at least one object detection step on the architectural floor plan image for detecting and classifying a plurality of objects in the architectural floor plan image to output object data, the object data including object classes and object locations for the plurality of objects within the architectural floor plan image;
performing, via the deep learning model, at least one text analysis step for identifying and extracting text from the architectural floor plan image to output text data, the text data including textual content and textual content locations within the architectural floor plan image;
performing, via the deep learning model, at least one segmentation step for dividing the architectural floor plan image into at least one region;
determining, via the deep learning model, a semantic label for each region of the at least one region based, at least in part, on the object data and the text data; and
quantifying, via the deep learning model, the building parameters of the at least one region based on the semantic label of the at least one region.
